(19) United States
(12) Patent Application Publication
(10) Pub. No.: US 2019/0273178 A1
(43) Pub. Date: Sep. 5, 2019

(54) Decreased Photon Reabsorption in Emissive Quantum Dots

(71) Applicant: NANOSYS, INC., Milpitas, CA (US)

(72) Inventors: Ilan Jen-La Plante, San Jose, CA (US); Chunming WANG, Milpitas, CA (US); Ernest Chung-Wei LEE, Palo Alto, CA (US)

(73) Assignee: NANOSYS, INC., Milpitas, CA (US)

(21) Appl. No.: 16/292,700

(22) Filed: Mar. 5, 2019

Related U.S. Application Data
(60) Provisional application No. 62/638,533, filed on Mar. 5, 2018.

(51) Int. Cl. H01L 33/06; H01L 33/00; C09K 11/08; C09K 11/62; C09K 11/56; C09K 11/54

(52) U.S. Cl. CPC H01L 33/06; H01L 33/005; C09K 11/0855; C09K 11/54; C09K 11/0811; C09K 11/56; C09K 11/62

(57) ABSTRACT

The invention is in the field of nanostructure synthesis. Provided are highly luminescent nanostructures, particularly highly luminescent quantum dots, comprising a nanocrystal core and a thin inner shell layer. The nanostructures may have an additional outer shell layer. Also provided are methods of preparing the nanostructures, films comprising the nanostructures, and devices comprising the nanostructures.

### BACKGROUND OF THE INVENTION

### Field of the Invention

The invention is in the field of nanostructure synthesis. Provided are highly luminescent nanostructures, particularly highly luminescent quantum dots, comprising a nanocrystal core and a thin inner shell layer. The nanostructures may have additional outer shell layers. Also provided are methods of preparing the nanostructures, films comprising the nanostructures, and devices comprising the nanostructures.

### Background of the Invention

Decreasing photon reabsorption in emissive quantum dots is critical to performance in applications such as quantum dot color filters. When deployed at high optical densities, photon reabsorption can lead to reduced photoconversion efficiencies and undesirable red shifts in peak emission wavelength (PWL).

An alternative approach to reduce photon reabsorption is to increase the energetic separation between the absorbance and emission spectra, or the effective Stokes shift of the material. One method to increase the Stokes shift is to grow a very thick shell such that nearly all absorbance occurs in the shell material and emission occurs only from the core. U.S. Pat. No. 7,935,419 describes nanocrystal quantum dots having an inner core having an average diameter of at least 1.5 nm and a thick outer shell having at least seven monolayers that displayed an enhanced Stokes shift when compared to smaller nanocrystal quantum dots. However, this method is limited by the large volume of the resulting quantum dots and negative effects of lattice strain for material systems with limited interfacial alloying between core and shell.

Other methods of achieving a large effective Stokes shift include down-converting emitters (e.g., using rare-earth or transition-metal doped materials) or type-II staggered band alignment core/shell systems. However, both strategies typically result in long photoluminescence lifetimes, which can cause lower photoluminescence quantum yield (PLQY) values in the presence of competitive non-radiative processes.

A need exists to prepare nanostructure compositions that have improved stability and result in improved optical properties when used to prepare a nanostructure film.

### BRIEF SUMMARY OF THE INVENTION

The present invention is directed to a nanostructure comprising a nanocrystal core and at least one thin inner shell, wherein the at least one thin inner shell has a thickness of between about 0.01 nm and about 0.35 nm, and wherein the nanostructure exhibits an effective Stokes shift of between about 25 nm and about 125 nm.

In some embodiments, the nanocrystal core is selected from the group consisting of Si, Ge, Sn, Se, Te, B, C, P, BN, BP, BAs, AlN, AlP, AlAs, AlSb, GaN, GaP, GaAs, GaSb, InN, InP, InAs, InSb, ZnO, ZnS, ZnSe, ZnTe, CdS, CdSe, CdSeZn, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, Al₂CO, and combinations thereof.

In some embodiments, the nanocrystal core comprises InP.

In some embodiments, the nanostructure comprises at least one thin inner shell selected from the group consisting of CdS, CdSe, CdO, CdTe, ZnS, ZnO, ZnSe, ZnTe, MgTe, GaAs, GaSb, GaN, HgO, HgS, HgSe, HgTe, InAs, InSb, InN, AlAs, AlN, AlSb AlS, PbS, PbO, PbSe, PbTe, MgO, MgS, MgSe, MgTe, CuCl, Ge, Si, and alloys thereof.

In some embodiments, the nanostructure comprises one thin inner shell.

In some embodiments, the nanostructure comprises at least one thin inner shell comprising ZnS.

In some embodiments, the thickness of the at least one thin inner shell of the nanostructure is between about 0.01 nm and about 0.25 nm.

In some embodiments, the thickness of the at least one thin inner shell of the nanostructure is between about 0.01 nm and about 0.15 nm.

In some embodiments, the nanostructure exhibits an effective Stokes shift of between about 25 nm and about 50 nm.

In some embodiments, the nanostructure further comprises at least one outer shell.

In some embodiments, the nanostructure further comprises at least one outer shell selected from the group consisting of CdS, CdSe, CdO, CdTe, ZnS, ZnO, ZnSe, ZnTe, MgTe, GaAs, GaSb, GaN, HgO, HgS, HgSe, HgTe, InAs, InSb, InN, AlAs, AlN, AlSb, AlS, PbS, PbO, PbSe, PbTe, MgO, MgS, MgSe, MgTe, CuCl, Ge, Si, and alloys thereof. In some embodiments, the at least one outer shell comprises ZnSe.

In some embodiments, the nanostructure further comprises two outer shells.

In some embodiments, the nanostructure comprises a nanocrystal core comprising InP, at least one thin inner shell comprising ZnS, and two outer shells, and the nanostructure exhibits an effective Stokes shift of between about 25 nm and about 50 nm.

The present invention is also directed to a method of making the nanostructure comprising:
(a) admixing a first core precursor, a second core precursor, a first inner shell precursor, and a second inner shell precursor; and
(b) raising the temperature of the admixture in (a) to a temperature between about 200° C. and about 350° C.;
   to provide a nanostructure.

In some embodiments, the admixing in (a) further comprises a solvent.

In some embodiments, the solvent is selected from the group consisting of 1-octadecene, 1-hexadecene, 1-eicosene, eicosane, octadecane, hexadecane, tetradecane, squalene, squalane, trioctylphosphine oxide, trioctylamine, trioctylphosphine, dioctyl ether, and combinations thereof.

In some embodiments, the solvent comprises 1-octadecene.

In some embodiments, the admixing in (a) is at a temperature between about 0° C. and about 150° C.

In some embodiments, the first core precursor is selected from the group consisting of a cadmium source, a zinc source, an aluminum source, a gallium source, or an indium source.

In some embodiments, the first core precursor comprises an indium source.

In some embodiments, the second core precursor is selected from the group consisting of a phosphorus source, a nitrogen source, an arsenic source, a sulfur source, a selenium source, or a tellurium source.

In some embodiments, the second core precursor comprises a phosphorus source.

In some embodiments, the first inner shell precursor is selected from the group consisting of a cadmium source, a zinc source, an aluminum source, a gallium source, or an indium source.

In some embodiments, the first inner shell precursor comprises a zinc source.

In some embodiments, the second inner shell precursor is selected from the group consisting of a phosphorus source, a nitrogen source, an arsenic source, a sulfur source, a selenium source, or a tellurium source.

In some embodiments, the second inner shell precursor comprises a sulfur source.

In some embodiments, the first core precursor comprises indium myristate, the second core precursor comprises tris(trimethyl)phosphine, the first inner shell precursor comprises zinc oleate, and the second inner shell precursor comprises dodecanethiol.

In some embodiments, the temperature of the admixture is raised in (b) to a temperature between about 280° C. and about 310° C.

In some embodiments, the temperature of the admixture in (b) is maintained until the admixture shows an absorbance maximum by UV-vis spectroscopy of between about 425 nm and about 450 nm.

In some embodiments, the method further comprises isolating the nanostructure.

In some embodiments, the method of making the nanostructure comprises:
(a) admixing a first inner shell precursor and a solvent;
(b) raising, lowering, or maintaining the temperature of the admixture in (a) to a temperature between about 50° C. and about 250° C.; and
(c) adding a nanostructure core and a second inner shell precursor to the admixture in (b);
   to provide a nanostructure.

In some embodiments, the solvent is selected from the group consisting of 1-octadecene, 1-hexadecene, 1-eicosene, eicosane, octadecane, hexadecane, tetradecane, squalene, squalane, trioctylphosphine oxide, trioctylamine, trioctylphosphine, dioctyl ether, and combinations thereof.

In some embodiments, the solvent comprises 1-octadecene.

In some embodiments, the admixing in (a) is at a temperature between about 0° C. and about 150° C.

In some embodiments, the first inner shell precursor is selected from the group consisting of a cadmium source, a zinc source, an aluminum source, a gallium source, or an indium source.

In some embodiments, the first inner shell precursor comprises an zinc source.

In some embodiments, the temperature in (b) is between about 50° C. and about 150° C.

In some embodiments, the nanostructure core in (c) is selected from the group consisting of Si, Ge, Sn, Se, Te, B, C, P, BN, BP, BAs, AlN, AlP, AlAs, AlSb, GaN, GaP, GaAs, GaSb, InN, InP, InAs, InSb, ZnO, ZnS, ZnSe, ZnTe, CdS, CdSe, CdSeZn, CdTe, HgS, HgSe, HgTe, BeS, BeSe, BeTe, MgS, MgSe, GeS, GeSe, GeTe, SnS, SnSe, SnTe, PbO, PbS, Pb Se, PbTe, CuF, CuCl, CuBr, CuI, Si₃N₄, Ge₃N₄, Al₂O₃, Al₂CO₃ and combinations thereof.

In some embodiments, the nanostructure core in (c) comprises InP.

In some embodiments, the second inner shell precursor is selected from the group consisting of a phosphorus source, a nitrogen source, an arsenic source, a sulfur source, a selenium source, or a tellurium source.

In some embodiments, the second inner shell precursor comprises a zinc source.

In some embodiments, the first inner shell precursor comprises zinc oleate, the nanostructure core comprises InP, and the second inner shell precursor comprises dodecanethiol.

In some embodiments, the temperature of the admixture in (b) is maintained until a sample taken from the admixture shows an absorbance maximum by UV-vis spectroscopy of between about 425 nm and about 450 nm.

In some embodiments, the method of making the nanostructure further comprises isolating the nanostructure.

In some embodiments, the method of making the nanostructure comprises:
(a) obtaining a solution comprising a first outer shell precursor;
(b) raising, lowering, or maintaining the temperature of the solution obtained in (a) to between about 50° C. and about 250° C.;
(c) adding the core/inner thin shell nanostructure prepared by the method of any one of claims 15-45 to the solution of (b);
(d) adding a second outer shell precursor; and
(e) raising, lowering, or maintaining the temperature to between about 200° C. and about 350° C.;
   to provide a nanostructure.

In some embodiments, the method further comprises:
(f) adding a third outer shell precursor, wherein the third outer shell precursor in (f) is different from the second outer shell precursor in (d).

In some embodiments, the introducing in (a) further comprises a solvent.

In some embodiments, the solvent is selected from the group consisting of 1-octadecene, 1-hexadecene, 1-eicosene, eicosane, octadecane, hexadecane, tetradecane, squalene, squalane, trioctylphosphine oxide, trioctylamine, trioctylphosphine, dioctyl ether, and combinations thereof.

In some embodiments, the solvent comprises 1-octadecene.

In some embodiments, the admixing in (a) is at a temperature between about 0° C. and about 150° C.

In some embodiments, the first outer shell precursor is selected from the group consisting of a cadmium source, a zinc source, an aluminum source, a gallium source, or an indium source.

In some embodiments, the first outer shell precursor comprises an zinc source.

In some embodiments, the temperature in (b) is between about 50° C. and about 150° C.

In some embodiments, the core/inner thin shell nanostructure was prepared by a method of the present invention.

In some embodiments, the second outer shell precursor is selected from the group consisting of a phosphorus source, a nitrogen source, an arsenic source, a sulfur source, a selenium source, or a tellurium source.

In some embodiments, the second outer shell precursor comprises a selenium source.

In some embodiments, the temperature in (e) is between about 280° C. and about 310° C.

In some embodiments, the third outer shell precursor is selected from the group consisting of a phosphorus source, a nitrogen source, an arsenic source, a sulfur source, a selenium source, or a tellurium source.

In some embodiments, the third outer shell precursor comprises a sulfur source.

In some embodiments, the first outer shell precursor comprises zinc oleate, the second outer shell precursor comprises trioctylphosphine selenide, and the third outer shell precursor comprises dodecanethiol.

In some embodiments, the method further comprises isolating the nanostructure.

### BRIEF DESCRIPTION OF THE DRAWINGS

The accompanying drawings, which are incorporated herein and form a part of the specification, illustrate the present invention and, together with the description, further serve to explain the principles of the invention and to enable a person skilled in the pertinent art to make and use the invention.

FIG. 1 is a line graph showing the absorbance peak maximum (triangles) and the half width at half maximum (circles) as a function of reaction time at 300° C. for InP/ZnS core/inner thin shell nanostructures synthesized using the method of Example 3.

FIG. 2 is a transmission electron microscropy (TEM) image for InP/ZnS core/inner thin shell nanostructures prior to shelling having an average diameter of 2.1 nm.

FIG. 3 is a TEM image for InP/ZnS core/inner thin shell nanostructures after shelling with ZnSe and ZnS to produce InP/ZnS/ZnSe/ZnS core/shell nanostructures with an average diameter of 6.8 nm.

FIG. 4 is a line graph showing the absorbance (solid line) and the emission (dashed line) spectra of InP/ZnS/ZnSe/ZnS core/shell nanostructures with an effective Stokes shift of 34 nm. The dashed vertical line represents an excitation wavelength of 450 nm.

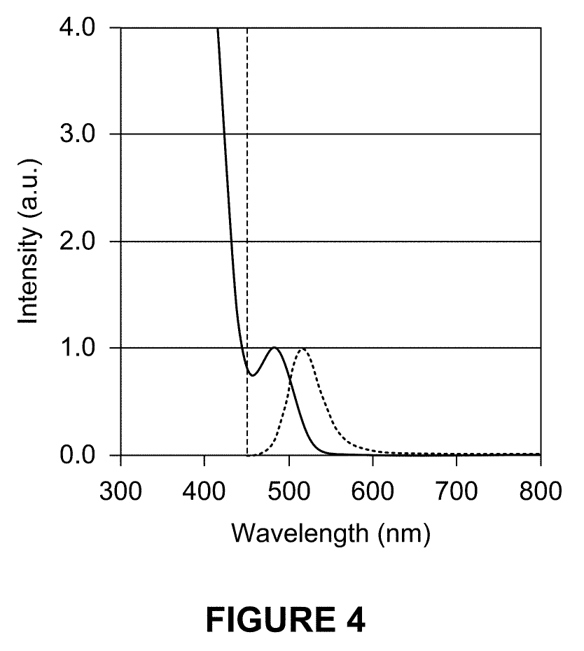

FIG. 5 is a bar graph showing the effective Stokes shift and core-to-core/shell red shift as a function of the inner thin ZnS shell thickness for InP/ZnS/ZnSe/ZnS core/shell nanostructures.

### DETAILED DESCRIPTION OF THE INVENTION

Unless defined otherwise, all technical and scientific terms used herein have the same meaning as commonly understood by one of ordinary skill in the art to which the invention pertains. The following definitions supplement those in the art and are directed to the current application and are not to be imputed to any related or unrelated case, e.g., to any commonly owned patent or application. Although any methods and materials similar or equivalent to those described herein can be used in practice for testing, the preferred materials and methods are described herein. Accordingly, the terminology used herein is for the purpose of describing particular embodiments only, and is not intended to be limiting.

As used in this specification and the appended claims, the singular forms “a,” “an,” and “the” include plural referents unless the context clearly dictates otherwise. Thus, for example, reference to “a nanostructure” includes a plurality of such nanostructures, and the like.

The term “about” as used herein indicates the value of a given quantity varies by ±10% of the value. For example, “about 100 nm” encompasses a range of sizes from 90 nm to 110 nm, inclusive.

A “nanostructure” is a structure having at least one region or characteristic dimension with a dimension of less than about 500 nm. In some embodiments, the nanostructure has a dimension of less than about 200 nm, less than about 100 nm, less than about 50 nm, less than about 20 nm, or less than about 10 nm. Typically, the region or characteristic dimension will be along the smallest axis of the structure. Examples of such structures include nanowires, nanorods, nanotubes, branched nanostructures, nanotetrapods, tripods, bipods, nanocrystals, nanodots, quantum dots, nanoparticles, and the like. Nanostructures can be, e.g., substantially crystalline, substantially monocrystalline, polycrystalline, amorphous, or a combination thereof. In some embodiments, each of the three dimensions of the nanostructure has a dimension of less than about 500 nm, less than about 200 nm, less than about 100 nm, less than about 50 nm, less than about 20 nm, or less than about 10 nm.

The term “heterostructure” when used with reference to nanostructures refers to nanostructures characterized by at least two different and/or distinguishable material types. Typically, one region of the nanostructure comprises a first material type, while a second region of the nanostructure comprises a second material type. In certain embodiments, the nanostructure comprises a core of a first material and at least one shell of a second (or third etc.) material, where the different material types are distributed radially about the long axis of a nanowire, a long axis of an arm of a branched nanowire, or the center of a nanocrystal, for example. A shell can but need not completely cover the adjacent materials to be considered a shell or for the nanostructure to be considered a heterostructure; for example, a nanocrystal characterized by a core of one material covered with small islands of a second material is a heterostructure. In other embodiments, the different material types are distributed at different locations within the nanostructure; e.g., along the major (long) axis of a nanowire or along a long axis of arm of a branched nanowire. Different regions within a heterostructure can comprise entirely different materials, or the different regions can comprise a base material (e.g., silicon) having different dopants or different concentrations of the same dopant.

As used herein, the “diameter” of a nanostructure refers to the diameter of a cross-section normal to a first axis of the nanostructure, where the first axis has the greatest difference in length with respect to the second and third axes (the second and third axes are the two axes whose lengths most nearly equal each other). The first axis is not necessarily the longest axis of the nanostructure; e.g., for a disk-shaped nanostructure, the cross-section would be a substantially circular cross-section normal to the short longitudinal axis of the disk. Where the cross-section is not circular, the diameter is the average of the major and minor axes of that cross-section. For an elongated or high aspect ratio nanostructure, such as a nanowire, the diameter is measured across a cross-section perpendicular to the longest axis of the nanowire. For a spherical nanostructure, the diameter is measured from one side to the other through the center of the sphere.

The terms “crystalline” or “substantially crystalline,” when used with respect to nanostructures, refer to the fact that the nanostructures typically exhibit long-range ordering across one or more dimensions of the structure. It will be understood by one of skill in the art that the term “long range ordering” will depend on the absolute size of the specific nanostructures, as ordering for a single crystal cannot extend beyond the boundaries of the crystal. In this case, “long-range ordering” will mean substantial order across at least the majority of the dimension of the nanostructure. In some instances, a nanostructure can bear an oxide or other coating, or can be comprised of a core and at least one shell. In such instances it will be appreciated that the oxide, shell(s), or other coating can but need not exhibit such ordering (e.g. it can be amorphous, polycrystalline, or otherwise). In such instances, the phrase “crystalline,” “substantially crystalline,” “substantially monocrystalline,” or “monocrystalline” refers to the central core of the nanostructure (excluding the coating layers or shells). The terms “crystalline” or “substantially crystalline” as used herein are intended to also encompass structures comprising various defects, stacking faults, atomic substitutions, and the like, as long as the structure exhibits substantial long range ordering (e.g., order over at least about 80% of the length of at least one axis of the nanostructure or its core). In addition, it will be appreciated that the interface between a core and the outside of a nanostructure or between a core and an adjacent shell or between a shell and a second adjacent shell may contain non-crystalline regions and may even be amorphous. This does not prevent the nanostructure from being crystalline or substantially crystalline as defined herein.

The term “monocrystalline” when used with respect to a nanostructure indicates that the nanostructure is substantially crystalline and comprises substantially a single crystal. When used with respect to a nanostructure heterostructure comprising a core and one or more shells, “monocrystalline” indicates that the core is substantially crystalline and comprises substantially a single crystal.

A “nanocrystal” is a nanostructure that is substantially monocrystalline. A nanocrystal thus has at least one region or characteristic dimension with a dimension of less than about 500 nm. In some embodiments, the nanocrystal has a dimension of less than about 200 nm, less than about 100 nm, less than about 50 nm, less than about 20 nm, or less than about 10 nm. The term “nanocrystal” is intended to encompass substantially monocrystalline nanostructures comprising various defects, stacking faults, atomic substitutions, and the like, as well as substantially monocrystalline nanostructures without such defects, faults, or substitutions. In the case of nanocrystal heterostructures comprising a core and one or more shells, the core of the nanocrystal is typically substantially monocrystalline, but the shell(s) need not be. In some embodiments, each of the three dimensions of the nanocrystal has a dimension of less than about 500 nm, less than about 200 nm, less than about 100 nm, less than about 50 nm, less than about 20 nm, or less than about 10 nm.

The term “quantum dot” (or “dot”) refers to a nanocrystal that exhibits quantum confinement or exciton confinement. Quantum dots can be substantially homogenous in material properties, or in certain embodiments, can be heterogeneous, e.g., including a core and at least one shell. The optical properties of quantum dots can be influenced by their particle size, chemical composition, and/or surface composition, and can be determined by suitable optical testing available in the art. The ability to tailor the nanocrystal size, e.g., in the range between about 1 nm and about 15 nm, enables photoemission coverage in the entire optical spectrum to offer great versatility in color rendering.

A “ligand” is a molecule capable of interacting (whether weakly or strongly) with one or more facets of a nanostructure, e.g., through covalent, ionic, van der Waals, or other molecular interactions with the surface of the nanostructure.

“Photoluminescence quantum yield” (PLQY) is the ratio of photons emitted to photons absorbed, e.g., by a nanostructure or population of nanostructures. As known in the art, quantum yield is typically determined by a comparative method using well-characterized standard samples with known quantum yield values.

“Peak emission wavelength” (PWL) is the wavelength where the radiometric emission spectrum of the light source reaches its maximum.

As used herein, the term “shell” refers to material deposited onto the core or onto previously deposited shells of the same or different composition and that result from a single act of deposition of the shell material. The exact shell thickness depends on the material as well as the precursor input and conversion and can be reported in nanometers or monolayers. As used herein, “target shell thickness” refers to the intended shell thickness used for calculation of the required precursor amount. As used herein, “actual shell thickness” refers to the actually deposited amount of shell material after the synthesis and can be measured by methods known in the art. By way of example, actual shell thickness can be measured by comparing particle diameters determined from transmission electron microscopy (TEM) images of nanocrystals before and after a shell synthesis.

As used herein, the term “full width at half-maximum” (FWHM) is a measure of the size distribution of nanoparticles. The emission spectra of nanoparticles generally have the shape of a Gaussian curve. The width of the Gaussian curve is defined as the FWHM and gives an idea of the size distribution of the particles. A smaller FWHM corresponds to a narrower quantum dot nanocrystal size distribution. FWHM is also dependent upon the peak emission wavelength.

As used herein, the term “half width at half-maximum” (HWHM) is a measure of the size distribution of nanoparticles extracted from UV-vis spectroscopy curves. A HWHM on the low-energy side of the first exciton absorption peak can be used as a suitable indicator of the size distribution, with smaller HWHM values corresponding to narrower size distributions.

### Nanostructure Composition

In some embodiments, the present disclosure provides a nanostructure composition comprising a nanocrystal core and at least one thin inner shell, wherein the at least one thin inner shell has a thickness of between about 0.01 nm and about 0.35 nm, and wherein the nanostructure exhibits an effective Stokes shift of between about 25 nm and about 125 nm.

In some embodiments, the present disclosure provides a nanostructure composition comprising a nanocrystal core, at least one thin inner shell, and at least one outer shell, wherein the at least one thin inner shell has a thickness of between about 0.01 nm and about 0.35 nm, and wherein the nanostructure exhibits an effective Stokes shift of between about 25 nm and about 125 nm.

In some embodiments, the nanostructure is a quantum dot.

### Nanostructure Core

The nanostructures for use in the present disclosure can be produced from any suitable material, suitably an inorganic material, and more suitably an inorganic conductive or semiconductive material.

In some embodiments, the nanostructure comprises a semiconductor core.

Suitable semiconductor core materials include any type of semiconductor, including Group II-VI, Group III-V, Group IV-VI, and Group IV semiconductors. Suitable semiconductor core materials include, but are not limited to, Si, Ge, Sn, Se, Te, B, C (including diamond), P, BN, BP, BAs, AlN, AlP, AlAs, AlSb, GaN, GaP, GaAs, GaSb, InN, InP, InAs, InSb, ZnO, ZnS, ZnSe, ZnTe, CdS, CdSe, CdSeZn, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, Al₂CO, and combinations thereof.

The synthesis of Group II-VI nanostructures has been described in U.S. Pat. Nos. 6,225,198, 6,322,901, 6,207,229, 6,607,829, 7,060,243, 7,374,824, 6,861,155, 7,125,605, 7,566,476, 8,158,193, and 8,101,234 and in U.S. Patent Appl. Publication Nos. 2011/0262752 and 2011/0263062. In some embodiments, the core is a Group II-VI nanocrystal selected from the group consisting of ZnO, ZnSe, ZnS, ZnTe, CdO, CdSe, CdS, CdTe, HgO, HgSe, HgS, and HgTe. In some embodiments, the core is a nanocrystal selected from the group consisting of ZnSe, ZnS, CdSe, or CdS.

Although Group II-VI nanostructures such as CdSe and CdS quantum dots can exhibit desirable luminescence behavior, issues such as the toxicity of cadmium limit the applications for which such nanostructures can be used. Less toxic alternatives with favorable luminescence properties are thus highly desirable. Group III-V nanostructures in general and InP-based nanostructures in particular, offer the best known substitute for cadmium-based materials due to their compatible emission range.

In some embodiments, the nanostructures are free from cadmium. As used herein, the term “free of cadmium” is intended that the nanostructures contain less than 100 ppm by weight of cadmium. The Restriction of Hazardous Substances (RoHS) compliance definition requires that there must be no more than 0.01% (100 ppm) by weight of cadmium in the raw homogeneous precursor materials. The cadmium level in the Cd-free nanostructures of the present invention is limited by the trace metal concentration in the precursor materials. The trace metal (including cadmium) concentration in the precursor materials for the Cd-free nanostructures, can be measured by inductively coupled plasma mass spectroscopy (ICP-MS) analysis, and are on the parts per billion (ppb) level. In some embodiments, nanostructures that are “free of cadmium” contain less than about 50 ppm, less than about 20 ppm, less than about 10 ppm, or less than about 1 ppm of cadmium.

In some embodiments, the core is a Group III-V nanostructure. In some embodiments, the core is a Group III-V nanocrystal selected from the group consisting of BN, BP, BAs, BSb, AlN, AlP, AlAs, AlSb, GaN, GaP, GaAs, GaSb, InN, InP, InAs, and InSb. In some embodiments, the core is a InP nanocrystal.

The synthesis of Group III-V nanostructures has been described in U.S. Pat. Nos. 5,505,928, 6,306,736, 6,576,291, 6,788,453, 6,821,337, 7,138,098, 7,557,028, 8,062,967, 7,645,397, and 8,282,412 and in U.S. Patent Appl. Publication No. 2015/236195. Synthesis of Group III-V nanostructures has also been described in Wells, R. L., et al., “The use of tris(trimethylsilyl)arsine to prepare gallium arsenide and indium arsenide,” Chem. Mater. 1:4-6 (1989) and in Guzelian, A. A., et al., “Colloidal chemical synthesis and characterization of InAs nanocrystal quantum dots,” Appl. Phys. Lett. 69: 1432-1434 (1996).

Synthesis of InP-based nanostructures has been described, e.g., in Xie, R., et al., “Colloidal InP nanocrystals as efficient emitters covering blue to near-infrared,” J. Am. Chem. Soc. 129:15432-15433 (2007); Micic, O. I., et al., “Core-shell quantum dots of lattice-matched ZnCdSe₂ shells on InP cores: Experiment and theory,” J. Phys. Chem. B 104:12149-12156 (2000); Liu, Z., et al., “Coreduction colloidal synthesis of III-V nanocrystals: The case of InP,” Angew. Chem. Int. Ed. Engl. 47:3540-3542 (2008); Li, L. et al., “Economic synthesis of high quality InP nanocrystals using calcium phosphide as the phosphorus precursor,” Chem. Mater. 20:2621-2623 (2008); D. Battaglia and X. Peng, “Formation of high quality InP and InAs nanocrystals in a noncoordinating solvent,” Nano Letters 2:1027-1030 (2002); Kim, S., et al., “Highly luminescent InP/GaP/ZnS nanocrystals and their application to white light-emitting diodes,” J. Am. Chem. Soc. 134:3804-3809 (2012); Nann, T., et al., “Water splitting by visible light: A nanophotocathode for hydrogen production,” Angew. Chem. Int. Ed. 49:1574-1577 (2010); Borchert, H., et al., “Investigation of ZnS passivated InP nanocrystals by XPS,” Nano Letters 2:151-154 (2002); L. Li and P. Reiss, “One-pot synthesis of highly luminescent InP/ZnS nanocrystals without precursor injection,” J. Am. Chem. Soc. 130:11588-11589 (2008); Hussain, S., et al. “One-pot fabrication of high-quality InP/ZnS (core/shell) quantum dots and their application to cellular imaging,” Chemphyschem. 10:1466-1470 (2009); Xu, S., et al., “Rapid synthesis of high-quality InP nanocrystals,” J. Am. Chem. Soc. 128:1054-1055 (2006); Micic, O. I., et al., “Size-dependent spectroscopy of InP quantum dots,” J. Phys. Chem. B 101:4904-4912 (1997); Haubold, S., et al., “Strongly luminescent InP/ZnS core-shell nanoparticles,” Chemphyschem. 5:331-334 (2001); CrosGagneux, A., et al., “Surface chemistry of InP quantum dots: A comprehensive study,” J. Am. Chem. Soc. 132:18147-18157 (2010); Micic, O. I., et al., “Synthesis and characterization of InP, GaP, and GalnP₂ quantum dots,” J. Phys. Chem. 99:7754-7759 (1995); Guzelian, A. A., et al., “Synthesis of size-selected, surface-passivated InP nanocrystals,” J. Phys. Chem. 100:7212-7219 (1996); Lucey, D. W., et al., “Monodispersed InP quantum dots prepared by colloidal chemistry in a non-coordinating solvent,” Chem. Mater. 17:3754-3762 (2005); Lim, J., et al., “InP@ZnSeS, core@composition gradient shell quantum dots with enhanced stability,” Chem. Mater. 23:4459-4463 (2011); and Zan, F., et al., “Experimental studies on blinking behavior of single InP/ZnS quantum dots: Effects of synthetic conditions and UV irradiation,” J. Phys. Chem. C 116:394-3950 (2012). However, such efforts have had only limited success in producing InP nanostructures with high quantum yields.

In some embodiments, the core is an InP nanocrystal. In some embodiments, the core precursors used to prepare an InP core comprise an indium source and a phosphine source.

In some embodiments, the indium source is indium myristate.

In some embodiments, the phosphine source is tris(trimethylsilyl)phosphine.

In some embodiments, the core is doped. In some embodiments, the dopant of the nanocrystal core comprises a metal, including one or more transition metals. In some embodiments, the dopant is a transition metal selected from the group consisting of Ti, Zr, Hf, V, Nb, Ta, Cr, Mo, W, Mn, Tc, Re, Fe, Ru, Os, Co, Rh, Ir, Ni, Pd, Pt, Cu, Ag, Au, and combinations thereof. In some embodiments, the dopant comprises a non-metal. In some embodiments, the dopant is ZnS, ZnSe, ZnTe, CdSe, CdS, CdTe, HgS, HgSe, HgTe, CuInS₂, CuInSe₂, AlN, AlP, AlAs, GaN, GaP, or GaAs.

In some embodiments, the core is purified before deposition of a shell. In some embodiments, the core is filtered to remove precipitate from the core solution.

In some embodiments, the diameter of the core is determined using quantum confinement. Quantum confinement in zero-dimensional nanocrystallites, such as quantum dots, arises from the spatial confinement of electrons within the crystallite boundary. Quantum confinement can be observed once the diameter of the material is of the same magnitude as the de Broglie wavelength of the wave function. The electronic and optical properties of nanoparticles deviate substantially from those of bulk materials. A particle behaves as if it were free when the confining dimension is large compared to the wavelength of the particle. During this state, the bandgap remains at its original energy due to a continuous energy state. However, as the confining dimension decreases and reaches a certain limit, typically in nanoscale, the energy spectrum becomes discrete. As a result, the bandgap becomes size-dependent.

### Inner Thin Shell

In some embodiments, the nanostructures of the present invention include a core and at least one inner thin shell. In some embodiments, the nanostructures of the present invention include a core and at least two inner thin shells. In some embodiments, the core and the inner thin shell comprise different materials. In some embodiments, the nanostructure comprises inner thin shells of different shell material.

In some embodiments, an inner thin shell deposits onto a core that comprises a mixture of Group II and VI elements. In some embodiments, an inner thin shell deposits onto a core comprising a nanocrystal selected from ZnSe, ZnS, CdSe, and CdS.

In some embodiments, an inner thin shell deposits onto a core that comprises a mixture of Group III and Group V elements. In some embodiments, the inner thin shell deposits onto a core comprising a nanocrystal selected from BN, BP, BAs, BSb, AlN, AlP, AlAs, AlSb, GaN, GaP, GaAs, GaSb, InN, InP, InAs, and InSb. In some embodiments, an inner thin shell deposits onto a core comprising InP.

In some embodiments, the inner thin shell comprises a mixture of at least two of zinc, selenium, sulfur, tellurium, and cadmium. In some embodiments, the inner thin shell comprises a mixture of two of zinc, selenium, sulfur, tellurium, and cadmium. In some embodiments, the inner thin shell comprises a mixture of three of zinc, selenium, sulfur, tellurium, and cadmium. In some embodiments, the inner thin shell comprises a mixture of: zinc and sulfur; zinc and selenium; zinc, sulfur, and selenium; zinc and tellurium; zinc, tellurium, and sulfur; zinc, tellurium, and selenium; zinc, cadmium, and sulfur; zinc, cadmium, and selenium; cadmium and sulfur; cadmium and selenium; cadmium, selenium, and sulfur; cadmium and zinc; cadmium, zinc, and sulfur; cadmium, zinc, and selenium; or cadmium, zinc, sulfur, and selenium.

The thickness of the inner thin shell can be controlled by varying the amount of precursor provided. For a given inner thin shell thickness, at least one of the precursors is optionally provided in an amount whereby, when a growth reaction is substantially complete, an inner thin shell of a predetermined thickness is obtained. If more than one different precursor is provided, either the amount of each precursor can be limited or one of the precursors can be provided in a limiting amount while the others are provided in excess.

In some embodiments, the core comprises a Group II element and the inner thin shell comprises a Group VI element. In some embodiments, the Group II element is zinc or cadmium. In some embodiments, the Group VI element is sulfur, selenium, or tellurium. In some embodiments, the molar ratio of the Group II element source and the Group VI element source is between about 0.01:1 and about 1:1.5, about 0.01:1 and about 1:1.25, about 0.01:1 and about 1:1, about 0.01:1 and about 1:0.75, about 0.01:1 and about 1:0.5, about 0.01:1 and about 1:0.25, about 0.01:1 and about 1:0.05, about 0.05:1 and about 1:1.5, about 0.05:1 and about 1:1.25, about 0.05:1 and about 1:1, about 0.05:1 and about 1:0.75, about 0.05:1 and about 1:0.5, about 0.05:1 and about 1:0.25, about 0.25:1 and about 1:1.5, about 0.25:1 and about 1:1.25, about 0.25:1 and about 1:1, about 0.25:1 and about 1:0.75, about 0.25:1 and about 1:0.5, about 0.5:1 and about 1:1.5, about 0.5:1 and about 1:1.25, about 0.5:1 and about 1:1, about 0.5:1 and about 1:0.75, about 0.75:1 and about 1:1.5, about 0.75:1 and about 1:1.25, about 0.75:1 and about 1:1, about 1:1 and about 1:1.5, about 1:1 and about 1:1.25, or about 1:1.25 and about 1:1.5.

In some embodiments, the core comprises a Group III element and the inner thin shell comprises a Group VI element. In some embodiments, the Group III element is gallium or indium. In some embodiments, the Group VI element is sulfur, selenium, or tellurium. In some embodiments, the molar ratio of the Group III element source and Group VI element source is between about 0.01:1 and about 1:1.5, about 0.01:1 and about 1:1.25, about 0.01:1 and about 1:1, about 0.01:1 and about 1:0.75, about 0.01:1 and about 1:0.5, about 0.01:1 and about 1:0.25, about 0.01:1 and about 1:0.05, about 0.05:1 and about 1:1.5, about 0.05:1 and about 1:1.25, about 0.05:1 and about 1:1, about 0.05:1 and about 1:0.75, about 0.05:1 and about 1:0.5, about 0.05:1 and about 1:0.25, about 0.25:1 and about 1:1.5, about 0.25:1 and about 1:1.25, about 0.25:1 and about 1:1, about 0.25:1 and about 1:0.75, about 0.25:1 and about 1:0.5, about 0.5:1 and about 1:1.5, about 0.5:1 and about 1:1.25, about 0.5:1 and about 1:1, about 0.5:1 and about 1:0.75, about 0.75:1 and about 1:1.5, about 0.75:1 and about 1:1.25, about 0.75:1 and about 1:1, about 1:1 and about 1:1.5, about 1:1 and about 1:1.25, or about 1:1.25 and about 1:1.5.

The thickness of the inner thin shell layer can be controlled by varying the amount of precursor provided and/or by use of longer reaction times and/or higher temperatures. For a given layer, at least one of the precursors is optionally provided in an amount whereby, when a growth reaction is substantially complete, a layer of a predetermined thickness is obtained. If more than one different precursor is provided, either the amount of each precursor can be limited or one of the precursors can be provided in a limiting amount while the others are provided in excess.

In some embodiments, where the core comprises indium and the inner thin shell comprises sulfur, the thickness of the thin inner shell is controlled by varying the molar ratio of the sulfur source to the indium source. In some embodiments, the molar ratio of the sulfur source to the indium source is between about 0.01:1 and about 1:1.5, about 0.01:1 and about 1:1.25, about 0.01:1 and about 1:1, about 0.01:1 and about 1:0.75, about 0.01:1 and about 1:0.5, about 0.01:1 and about 1:0.25, about 0.01:1 and about 1:0.05, about 0.05:1 and about 1:1.5, about 0.05:1 and about 1:1.25, about 0.05:1 and about 1:1, about 0.05:1 and about 1:0.75, about 0.05:1 and about 1:0.5, about 0.05:1 and about 1:0.25, about 0.25:1 and about 1:1.5, about 0.25:1 and about 1:1.25, about 0.25:1 and about 1:1, about 0.25:1 and about 1:0.75, about 0.25:1 and about 1:0.5, about 0.5:1 and about 1:1.5, about 0.5:1 and about 1:1.25, about 0.5:1 and about 1:1, about 0.5:1 and about 1:0.75, about 0.75:1 and about 1:1.5, about 0.75:1 and about 1:1.25, about 0.75:1 and about 1:1, about 1:1 and about 1:1.5, about 1:1 and about 1:1.25, or about 1:1.25 and about 1:1.5.

The thickness of the inner thin shell can be determined using techniques known to those of skill in the art. In some embodiments, the thickness of the inner thin shell is determined by comparing the average diameter of the nanostructure before and after the addition of the inner thin shell. In some embodiments, the average diameter of the nanostructure before and after the addition of the inner thin shell is determined by TEM. In some embodiments, the inner thin shell has a thickness of between about 0.01 nm and about 0.35 nm, about 0.01 nm and about 0.3 nm, about 0.01 nm and about 0.25 nm, about 0.01 nm and about 0.2 nm, about 0.01 nm and about 0.1 nm, about 0.01 nm and about 0.05 nm, about 0.05 nm and about 0.35 nm, about 0.05 nm and about 0.3 nm, about 0.05 nm and about 0.25 nm, about 0.05 nm and about 0.2 nm, about 0.05 nm and about 0.1 nm, about 0.1 nm and about 0.35 nm, about 0.1 nm and about 0.3 nm, about 0.1 nm and about 0.25 nm, about 0.1 nm and about 0.2 nm, about 0.2 nm and about 0.35 nm, about 0.2 nm and about 0.3 nm, about 0.2 nm and about 0.25 nm, about 0.25 nm and about 0.35 nm, about 0.25 nm and about 0.3 nm, or about 0.3 nm and about 0.35 nm.

In some embodiments, the inner thin shell is a ZnS shell. In some embodiments, the shell precursors used to prepare a ZnS shell comprise a zinc source and a sulfur source.

In some embodiments, the inner thin shell is a ZnSe shell. In some embodiments, the shell precursors used to prepare a ZnSe shell comprise a zinc source and a selenium source.

In some embodiments, the zinc source is a dialkyl zinc compound. In some embodiments, the zinc source is a zinc carboxylate. In some embodiments, the zinc source is diethylzinc, dimethylzinc, zinc acetate, zinc acetylacetonate, zinc iodide, zinc bromide, zinc chloride, zinc fluoride, zinc carbonate, zinc cyanide, zinc nitrate, zinc oleate, zinc oxide, zinc peroxide, zinc perchlorate, zinc sulfate, zinc hexanoate, zinc octanoate, zinc laurate, zinc myristate, zinc palmitate, zinc stearate, zinc dithiocarbamate, or mixtures thereof. In some embodiments, the zinc source is zinc oleate, zinc hexanoate, zinc octanoate, zinc laurate, zinc myristate, zinc palmitate, zinc stearate, zinc dithiocarbamate, or mixtures thereof. In some embodiments, the zinc source is zinc oleate.

In some embodiments, the sulfur source is selected from elemental sulfur, octanethiol, dodecanethiol, octadecanethiol, tributylphosphine sulfide, cyclohexyl isothiocyanate, toluenethiol, ethylene trithiocarbonate, allyl mercaptan, bis(trimethylsilyl) sulfide, trialkylthiourea, trioctylphosphine sulfide, zinc diethyldithiocarbamate, and mixtures thereof. In some embodiments, the sulfur source is an alkyl-substituted zinc dithiocarbamate. In some embodiments, the sulfur source is zinc diethylthiocarbamate. In some embodiments, the sulfur source is dodecanethiol.

In some embodiments, the selenium source is an alkyl-substituted selenourea. In some embodiments, the selenium source is a phosphine selenide. In some embodiments, the selenium source is selected from trioctylphosphine selenide, tri(n-butyl)phosphine selenide, tri(sec-butyl)phosphine selenide, tri(tert-butyl)phosphine selenide, trimethylphosphine selenide, triphenylphosphine selenide, diphenylphosphine selenide, phenylphosphine selenide, tricyclohexylphosphine selenide, cyclohexylphosphine selenide, 1-octaneselenol, 1-dodecaneselenol, selenophenol, elemental selenium, hydrogen selenide, bis(trimethylsilyl) selenide, selenourea, and mixtures thereof. In some embodiments, the selenium source is tri(n-butyl)phosphine selenide, tri(sec-butyl)phosphine selenide, or tri(tert-butyl)phosphine selenide. In some embodiments, the selenium source is trioctylphosphine selenide.

In some embodiments, each inner thin shell is synthesized in the presence of at least one nanostructure ligand. Ligands can, e.g., enhance the miscibility of nanostructures in solvents or polymers (allowing the nanostructures to be distributed throughout a composition such that the nanostructures do not aggregate together), increase quantum yield of nanostructures, and/or preserve nanostructure luminescence (e.g., when the nanostructures are incorporated into a matrix). In some embodiments, the ligand(s) for the core synthesis and for the shell synthesis are the same. In some embodiments, the ligand(s) for the core synthesis and for the shell synthesis are different. Following synthesis, any ligand on the surface of the nanostructures can be exchanged for a different ligand with other desirable properties. Examples of ligands are disclosed in U.S. Pat. Nos. 7,572,395, 8,143,703, 8,425,803, 8,563,133, 8,916,064, 9,005,480, 9,139,770, and 9,169,435, and in U.S. Patent Application Publication No. 2008/0118755.

Ligands suitable for the synthesis of a shell are known by those of skill in the art. In some embodiments, the ligand is a fatty acid selected from the group consisting of lauric acid, caproic acid, myristic acid, palmitic acid, stearic acid, and oleic acid. In some embodiments, the ligand is an organic phosphine or an organic phosphine oxide selected from trioctylphosphine oxide (TOPO), trioctylphosphine (TOP), diphenylphosphine (DPP), triphenylphosphine oxide, and tributylphosphine oxide. In some embodiments, the ligand is an amine selected from the group consisting of dodecylamine, oleylamine, hexadecylamine, dioctylamine, and octadecylamine. In some embodiments, the ligand is oleic acid.

Production of a Core with Inner Thin Shell—Method A

In some embodiments, the present invention is directed to a method of producing a core/inner thin shell nanostructure comprising:
(a) admixing a first core precursor, a second core precursor, a first inner shell precursor, and a second inner shell precursor; and
(b) raising the temperature of the admixture in (a) to a temperature between about 200° C. and about 350° C.;
   to provide a nanostructure.

In some embodiments, a core/inner thin inner shell nanostructure is produced in the presence of a solvent. In some embodiments, the solvent is selected from the group consisting of 1-octadecene, 1-hexadecene, 1-eicosene, eicosane, octadecane, hexadecane, tetradecane, squalene, squalane, trioctylphosphine oxide, trioctylamine, trioctylphosphine, and dioctyl ether. In some embodiments, the solvent is 1-octadecene.

In some embodiments, a first core precursor, a second core precursor, a first inner shell precursor, and a second inner shell precursor are admixed in (a) at a temperature between about 0° C. and about 150° C., about 0° C. and about 100° C., about 0° C. and about 50° C., about 0° and about 30° C., about 0° C. and about 20° C., about 20° C. and about 150° C., about 20° C. and about 100° C., about 20° C. and about 50° C., about 20° and about 30° C., about 30° C. and about 150° C., about 30° C. and about 100° C., about 30° C. and about 50° C., about 50° C. and about 150° C., about 50° C. and about 100° C., or about 100° C. and about 150° C. In some embodiments, a first core precursor, a second core precursor, a first inner shell precursor, and a second inner shell precursor are admixed in (a) at a temperature between about 20° C. and about 30° C.

In some embodiments, the first core precursor is a Group III core precursor. In some embodiments, the first core precursor is an aluminum source, a gallium source, or an indium source. In some embodiments, the first core precursor is an indium source. In some embodiments, the first core precursor is indium myristate.

In some embodiments, the second core precursor is a Group V core precursor. In some embodiments, the second core precursor is a nitrogen source, a phosphorus source, or an arsenic source. In some embodiments, the second core precursor is a phosphorus source. In some embodiments, the second core precursor is tris(trimethyl)phosphine.

In some embodiments, the first inner shell precursor is a Group II shell precursor. In some embodiments, the first inner shell precursor is a zinc source or a cadmium source. In some embodiments, the first inner shell precursor is a zinc source. In some embodiments, the first shell precursor is zinc oleate.

In some embodiments, the second inner shell precursor is a Group VI shell precursor. In some embodiments, the second inner shell precursor is sulfur, selenium, or tellurium. In some embodiments, the second inner shell precursor is a sulfur source. In some embodiments, the sulfur source is dodecanethiol.

In some embodiments, the temperature of the admixture is raised in (b) to a temperature between about 200° C. and about 350° C., about 200° C. and about 310° C., about 200° C. and about 280° C., about 200° C. and about 250° C., about 200° C. and about 225° C., about 225° C. and about 350° C., about 225° C. and about 310° C., about 225° C. and about 280° C., about 225° C. and about 250° C., about 250° C. and about 350° C., about 250° C. and about 310° C., about 250° C. and about 280° C., about 280° C. and about 350° C., about 280° C. and about 310° C., or about 310° C. and about 350° C. In some embodiments, the temperature of the admixture is elevated in (b) to a temperature between about 280° C. and about 310° C.

In some embodiments, the time for the temperature to reach the elevated temperature in (b) is between about 2 minutes and about 240 minutes, about 2 minutes and about 200 minutes, about 2 minutes and about 100 minutes, about 2 minutes and about 60 minutes, about 2 minutes and about 40 minutes, about 5 minutes and about 240 minutes, about 5 minutes and about 200 minutes, about 5 minutes and about 100 minutes, about 5 minutes and about 60 minutes, about 5 minutes and about 40 minutes, about 10 minutes and about 240 minutes, about 10 minutes and about 200 minutes, about 10 minutes and about 100 minutes, about 10 minutes and about 60 minutes, about 10 minutes and about 40 minutes, about 40 minutes and about 240 minutes, about 40 minutes and about 200 minutes, about 40 minutes and about 100 minutes, about 40 minutes and about 60 minutes, about 60 minutes and about 240 minutes, about 60 minutes and about 200 minutes, about 60 minutes and about 100 minutes, about 100 minutes and about 240 minutes, about 100 minutes and about 200 minutes, or about 200 minutes and about 240 minutes.

In some embodiments, after the admixture reaches the elevated temperature in (b), the temperature is maintained for a period of between about 1 minute and about 240 minutes, about 1 minute and about 90 minutes, about 1 minute and about 60 minutes, about 1 minute and about 30 minutes, about 1 minute and about 15 minutes, about 1 minute and about 5 minutes, about 5 minutes and about 240 minutes, about 5 minutes and about 90 minutes, about 5 minutes and about 60 minutes, about 5 minutes and about 30 minutes, about 5 minute and about 15 minutes, about 15 minutes and about 240 minutes, about 15 minutes and about 90 minutes, about 15 minutes and about 60 minutes, about 15 minutes and about 30 minutes, about 30 minutes and about 240 minutes, about 30 minutes and about 90 minutes, about 30 minutes and about 60 minutes, about 60 minutes and about 240 minutes, about 60 minutes and about 90 minutes, or about 90 minutes and about 240 minutes.

In some embodiments, the progress of the reaction is monitored by testing samples from the admixture or by in situ monitoring of the admixture using UV-vis spectroscopy. In some embodiments, after the admixture reaches the elevated temperature in (b), the temperature is maintained until the admixture shows an absorbance maximum by UV-vis spectroscopy of between about 350 nm and about 500 nm, about 350 nm and about 475 nm, about 350 nm and about 450 nm, about 350 nm and about 425 nm, about 350 nm and about 400 nm, about 350 nm and about 375 nm, about 375 nm and about 500 nm, about 375 nm and about 475 nm, about 375 nm and about 450 nm, about 375 nm and about 425 nm, about 375 nm and about 400 nm, about 400 nm and about 500 nm, about 400 nm and about 475 nm, about 400 nm and about 450 nm, about 400 nm and about 425 nm, about 425 nm and about 475 nm, about 425 nm and about 450 nm, about 450 nm and about 500 nm, about 450 nm and about 475 nm, or about 475 nm and about 500 nm. In some embodiments, after the admixture reaches the elevated temperature in (b), the temperature is maintained until a sample taken from the admixture shows an absorbance maximum by UV-vis spectroscopy of between about 425 nm and about 450 nm.

In some embodiments, additional shells are produced by further additions of shell material precursors that are added to the reaction mixture followed by maintaining at an elevated temperature. Typically, additional shell precursor is provided after reaction of the previous shell is substantially complete (e.g., when at least one of the previous precursors is depleted or removed from the reaction or when no additional growth is detectable). The further additions of precursor create additional shells.

In some embodiments, the nanostructure is cooled before the addition of additional shell material precursor to provide further shells. In some embodiments, the nanostructure is maintained at an elevated temperature before the addition of shell material precursor to provide further shells.

Production of a Core with Inner Thin Shell—Method B

In some embodiments, the present invention is directed to a method of producing a core/inner thin shell nanostructure comprising:
(a) admixing a first inner shell precursor and a solvent;
(b) raising, lowering, or maintaining the temperature of the admixture in (a) to a temperature between about 50° C. and about 250° C.; and
(c) adding a nanostructure core and a second inner shell precursor to the admixture in (b);
   to provide a nanostructure.

In some embodiments, a core/inner thin shell nanostructure is produced in the presence of a solvent. In some embodiments, the solvent is selected from the group consisting of 1-octadecene, 1-hexadecene, 1-eicosene, eicosane, octadecane, hexadecane, tetradecane, squalene, squalane, trioctylphosphine oxide, trioctylamine, trioctylphosphine, and dioctyl ether. In some embodiments, the solvent is 1-octadecene.

In some embodiments, a first inner shell precursor and solvent are admixed in (a) at a temperature between about 0° C. and about 150° C., about 0° C. and about 100° C., about 0° C. and about 50° C., about 0° C. and about 30° C., about 0° C. and about 20° C., about 20° C. and about 150° C., about 20° C. and about 100° C., about 20° C. and about 50° C., about 20° C. and about 30° C., about 30° C. and about 150° C., about 30° C. and about 100° C., about 30° C. and about 50° C., about 50° C. and about 150° C., about 50° C. and about 100° C., or about 100° C. and about 150° C. In some embodiments, the first inner shell precursor and solvent are admixed in (a) at a temperature between about 20° C. and about 30° C.

In some embodiments, the first inner shell precursor is a Group II shell precursor. In some embodiments, the first inner shell precursor is a zinc source or a cadmium source. In some embodiments, the first inner shell precursor is a zinc source. In some embodiments, the first shell precursor is zinc oleate.

In some embodiments, the admixing in (a) further comprises at least one nanostructure ligand. Ligands can, e.g., enhance the miscibility of nanostructures in solvents or polymers (allowing the nanostructures to be distributed throughout a composition such that the nanostructures do not aggregate together), increase quantum yield of nanostructures, and/or preserve nanostructure luminescence (e.g., when the nanostructures are incorporated into a matrix). In some embodiments, the ligand(s) for the core synthesis and for the shell synthesis are the same. In some embodiments, the ligand(s) for the core synthesis and for the shell synthesis are different. Following synthesis, any ligand on the surface of the nanostructures can be exchanged for a different ligand with other desirable properties. Examples of ligands are disclosed in U.S. Pat. Nos. 7,572,395, 8,143,703, 8,425,803, 8,563,133, 8,916,064, 9,005,480, 9,139,770, and 9,169,435, and in U.S. Patent Application Publication No. 2008/0118755.

In some embodiments, the ligand admixed with the first shell precursor and solvent in (a) is a fatty acid selected from the group consisting of lauric acid, caproic acid, myristic acid, palmitic acid, stearic acid, and oleic acid. In some embodiments, the ligand is an organic phosphine or an organic phosphine oxide selected from trioctylphosphine oxide (TOPO), trioctylphosphine (TOP), diphenylphosphine (DPP), triphenylphosphine oxide, and tributylphosphine oxide. In some embodiments, the ligand is an amine selected from the group consisting of dodecylamine, oleylamine, hexadecylamine, dioctylamine, and octadecylamine. In some embodiments, the ligand is lauric acid.

In some embodiments, the temperature of the admixture is raised, lowered, or maintained in (b) to a temperature between about 50° C. and about 250° C., about 50° C. and about 200° C., about 50° C. and about 150° C., about 50° C. and about 125° C., about 50° C. and about 100° C., about 50° C. and about 75° C., about 75° C. and about 250° C., about 75° C. and about 200° C., about 75° C. and about 150° C., about 75° C. and about 125° C., about 75° C. and about 100° C., about 100° C. and about 250° C., about 100° C. and about 200° C., about 100° C. and about 150° C., about 100° C. and about 125° C., about 125° C. and about 250° C., about 125° C. and about 200° C., about 125° C. and about 150° C., about 150° C. and about 250° C., about 150° C. and about 200° C., or about 200° C. and about 250° C. In some embodiments, the temperature of the admixture is raised, lowered, or maintained in (b) to a temperature between about 50° C. and about 150° C.

In some embodiments, the time for the temperature to reach the temperature in (b) is between about 2 minutes and about 240 minutes, about 2 minutes and about 200 minutes, about 2 minutes and about 100 minutes, about 2 minutes and about 60 minutes, about 2 minutes and about 40 minutes, about 5 minutes and about 240 minutes, about 5 minutes and about 200 minutes, about 5 minutes and about 100 minutes, about 5 minutes and about 60 minutes, about 5 minutes and about 40 minutes, about 10 minutes and about 240 minutes, about 10 minutes and about 200 minutes, about 10 minutes and about 100 minutes, about 10 minutes and about 60 minutes, about 10 minutes and about 40 minutes, about 40 minutes and about 240 minutes, about 40 minutes and about 200 minutes, about 40 minutes and about 100 minutes, about 40 minutes and about 60 minutes, about 60 minutes and about 240 minutes, about 60 minutes and about 200 minutes, about 60 minutes and about 100 minutes, about 100 minutes and about 240 minutes, about 100 minutes and about 200 minutes, or about 200 minutes and about 240 minutes.

In some embodiments, the second inner shell precursor is a Group VI shell precursor. In some embodiments, the second inner shell precursor is sulfur, selenium, or tellurium. In some embodiments, the second inner shell precursor is a sulfur source. In some embodiments, the sulfur source is dodecanethiol.

In some embodiments, the nanostructure core in (c) comprises a nanocrystal selected from BN, BP, Bas, BSb, AlN, AlP, AlAs, AlSb, GaN, GaP, GaAs, GaSb, InN, InP, InAs, and InSb. In some embodiments, the nanostructure core in (c) comprises InP.

In some embodiments, the temperature of the admixture in (c) is between about about 50° C. and about 250° C., about 50° C. and about 200° C., about 50° C. and about 150° C., about 50° C. and about 125° C., about 50° C. and about 100° C., about 50° C. and about 75° C., about 75° C. and about 250° C., about 75° C. and about 200° C., about 75° C. and about 150° C., about 75° C. and about 125° C., about 75° C. and about 100° C., about 100° C. and about 250° C., about 100° C. and about 200° C., about 100° C. and about 150° C., about 100° C. and about 125° C., about 125° C. and about 250° C., about 125° C. and about 200° C., about 125° C. and about 150° C., about 150° C. and about 250° C., about 150° C. and about 200° C., or about 200° C. and about 250° C. In some embodiments, the temperature of the admixture is elevated in (b) to a temperature between about 50° C. and about 150° C.

In some embodiments, the temperature is maintained in (c) for a time between about 2 minutes and about 240 minutes, about 2 minutes and about 200 minutes, about 2 minutes and about 100 minutes, about 2 minutes and about 60 minutes, about 2 minutes and about 40 minutes, about 5 minutes and about 240 minutes, about 5 minutes and about 200 minutes, about 5 minutes and about 100 minutes, about 5 minutes and about 60 minutes, about 5 minutes and about 40 minutes, about 10 minutes and about 240 minutes, about 10 minutes and about 200 minutes, about 10 minutes and about 100 minutes, about 10 minutes and about 60 minutes, about 10 minutes and about 40 minutes, about 40 minutes and about 240 minutes, about 40 minutes and about 200 minutes, about 40 minutes and about 100 minutes, about 40 minutes and about 60 minutes, about 60 minutes and about 240 minutes, about 60 minutes and about 200 minutes, about 60 minutes and about 100 minutes, about 100 minutes and about 240 minutes, about 100 minutes and about 200 minutes, or about 200 minutes and about 240 minutes.

In some embodiments, the progress of the reaction is monitored by testing samples from the admixture using UV-vis spectroscopy. In some embodiments, after addition of the nanostructure core in (c), the temperature is maintained until a sample taken from the admixture shows an absorbance maximum by UV-vis spectroscopy of between about 350 nm and about 500 nm, about 350 nm and about 475 nm, about 350 nm and about 450 nm, about 350 nm and about 425 nm, about 350 nm and about 400 nm, about 350 nm and about 375 nm, about 375 nm and about 500 nm, about 375 nm and about 475 nm, about 375 nm and about 450 nm, about 375 nm and about 425 nm, about 375 nm and about 400 nm, about 400 nm and about 500 nm, about 400 nm and about 475 nm, about 400 nm and about 450 nm, about 400 nm and about 425 nm, about 425 nm and about 475 nm, about 425 nm and about 450 nm, about 450 nm and about 500 nm, about 450 nm and about 475 nm, or about 475 nm and about 500 nm. In some embodiments, after addition of the nanostructure core in (c), the temperature is maintained until a sample taken from the admixture shows an absorbance maximum by UV-vis spectroscopy of between about 425 nm and about 450 nm.

In some embodiments, additional shells are produced by further additions of shell precursors that are added to the reaction mixture followed by maintaining at an elevated temperature. Typically, additional shell precursor is provided after reaction of the previous shell is substantially complete (e.g., when at least one of the previous precursors is depleted or removed from the reaction or when no additional growth is detectable). The further additions of precursor create additional shells.

In some embodiments, the nanostructure is cooled before the addition of additional shell precursor to provide further shells. In some embodiments, the nanostructure is maintained at an elevated temperature before the addition of shell precursor to provide further shells.

### Outer Shell Layers

In some embodiments, the nanostructures of the present invention comprise a core/inner thin shell and at least one outer shell layer. In some embodiments, the nanostructures of the present invention comprise a core/inner thin shell and at least two outer shell layers. In some embodiments, the nanostructures of the present invention comprise a core/inner thin shell and 1, 2, 3, or 4 outer shell layers.

In some embodiments, each outer shell layer comprises more than one monolayer. The number of monolayers is an average for all the nanostructures; therefore, the number of monolayers may be a fraction. In some embodiments, the number of monolayers in each outer shell layer is between about 0.25 and about 10, about 0.25 and about 8, about 0.25 and about 7, about 0.25 and about 6, about 0.25 and about 5, about 0.25 and about 4, about 0.25 and about 3, about 0.25 and about 2, about 2 and about 10, about 2 and about 8, about 2 and about 7, about 2 and about 6, about 2 and about 5, about 2 and about 4, about 2 and about 3, about 3 and about 10, about 3 and about 8, about 3 and about 7, about 3 and about 6, about 3 and about 5, about 3 and about 4, about 4 and about 10, about 4 and about 8, about 4 and about 7, about 4 and about 6, about 4 and about 5, about 5 and about 10, about 5 and about 8, about 5 and about 7, about 5 and about 6, about 6 and about 10, about 6 and about 8, about 6 and about 7, about 7 and about 10, about 7 and about 8, or about 8 and about 10. In some embodiments, each outer shell layer comprises between about 2 and about 3 monolayers.

The thickness of each outer shell layer can be controlled by varying the amount of precursor provided and/or by use of longer reaction times and/or higher temperatures. For a given layer; at least one of the precursors is optionally provided in an amount whereby, when a growth reaction is substantially complete, a layer of a predetermined thickness is obtained. If more than one different precursor is provided, either the amount of each precursor can be limited or one of the precursors can be provided in a limiting amount while the others are provided in excess.

The thickness of the outer shell layer can be determined using techniques known to those of skill in the art. In one embodiment, the thickness of each outer shell layer is determined by comparing the diameter of the core before and after the addition of each layer. In one embodiment, the diameter of the core before and after the addition of each layer is determined by transmission electron microscopy. In some embodiments, each outer shell layer has a thickness of between about 0.05 nm and about 2 nm, about 0.05 nm and about 1 nm, about 0.05 nm and about 0.5 nm, about 0.05 nm and about 0.3 nm, about 0.05 nm and about 0.1 nm, about 0.1 nm and about 2 nm, about 0.1 nm and about 1 mm, about 0.1 nm and about 0.5 nm, about 0.1 nm and about 0.3 nm, about 0.3 nm and about 2 nm, about 0.3 nm and about 1 nm, about 0.3 nm and about 0.5 nm, about 0.5 nm and about 2 nm, about 0.05 nm and about 1 nm, or about 1 nm and about 2 nm.

In some embodiments, each outer shell layer comprises a mixture of at least two of zinc, selenium, sulfur, tellurium, and cadmium. In some embodiments, each outer shell layer comprises a mixture of two of zinc, selenium, sulfur, tellurium, and cadmium. In some embodiments, each outer shell layer comprises a mixture of three of zinc, selenium, sulfur, tellurium, and cadmium. In some embodiments, each outer shell layer comprises a mixture of: zinc and sulfur; zinc and selenium; zinc, sulfur, and selenium; zinc and tellurium; zinc, tellurium, and sulfur; zinc, tellurium, and selenium; zinc, cadmium, and sulfur; zinc, cadmium, and selenium; cadmium and sulfur; cadmium and selenium; cadmium, selenium, and sulfur; cadmium and zinc; cadmium, zinc, and sulfur; cadmium, zinc, and selenium; or cadmium, zinc, sulfur, and selenium.

In some embodiments, the at least one outer shell layer is a ZnS shell. In some embodiments, the shell precursors used to prepare a ZnS outer shell comprise a zinc source and a sulfur source.

In some embodiments, the at least one outer shell layer is a ZnSe shell. In some embodiments, the shell precursors used to prepare a ZnSe shell comprise a zinc source and a selenium source.

In some embodiments, the zinc source used to prepare at least one outer shell layer is a dialkyl zinc compound. In some embodiments, the zinc source is a zinc carboxylate. In some embodiments, the zinc source is diethylzinc, dimethylzinc, zinc acetate, zinc acetylacetonate, zinc iodide, zinc bromide, zinc chloride, zinc fluoride, zinc carbonate, zinc cyanide, zinc nitrate, zinc oleate, zinc oxide, zinc peroxide, zinc perchlorate, zinc sulfate, zinc hexanoate, zinc octanoate, zinc laurate, zinc myristate, zinc palmitate, zinc stearate, zinc dithiocarbamate, or mixtures thereof. In some embodiments, the zinc source is zinc oleate, zinc hexanoate, zinc octanoate, zinc laurate, zinc myristate, zinc palmitate, zinc stearate, zinc dithiocarbamate, or mixtures thereof. In some embodiments, the zinc source is zinc oleate.

In some embodiments, the sulfur source used to prepare at least one outer shell layer is selected from elemental sulfur, octanethiol, dodecanethiol, octadecanethiol, tributylphosphine sulfide, cyclohexyl isothiocyanate, α-toluenethiol, ethylene trithiocarbonate, allyl mercaptan, bis(trimethylsilyl) sulfide, trialkylthiourea, trioctylphosphine sulfide, zinc diethyldithiocarbamate, and mixtures thereof. In some embodiments, the sulfur source is an alkyl-substituted zinc dithiocarbamate. In some embodiments, the sulfur source is zinc diethylthiocarbamate. In some embodiments, the sulfur source is dodecanethiol.

In some embodiments, the selenium source used to prepare at least one outer shell layer is an alkyl-substituted selenourea. In some embodiments, the selenium source is a phosphine selenide. In some embodiments, the selenium source is selected from trioctylphosphine selenide, tri(n-butyl)phosphine selenide, tri(sec-butyl)phosphine selenide, tri(tert-butyl)phosphine selenide, trimethylphosphine selenide, triphenylphosphine selenide, diphenylphosphine selenide, phenylphosphine selenide, tricyclohexylphosphine selenide, cyclohexylphosphine selenide, 1-octaneselenol, 1-dodecaneselenol, selenophenol, elemental selenium, hydrogen selenide, bis(trimethylsilyl) selenide, selenourea, and mixtures thereof. In some embodiments, the selenium source is tri(n-butyl)phosphine selenide, tri(sec-butyl)phosphine selenide, or tri(tert-butyl)phosphine selenide. In some embodiments, the selenium source is trioctylphosphine selenide.

In some embodiments, each outer shell layer is synthesized in the presence of at least one nanostructure ligand. Ligands can, e.g., enhance the miscibility of nanostructures in solvents or polymers (allowing the nanostructures to be distributed throughout a composition such that the nanostructures do not aggregate together), increase quantum yield of nanostructures, and/or preserve nanostructure luminescence (e.g., when the nanostructures are incorporated into a matrix). Following synthesis, any ligand on the surface of the nanostructures can be exchanged for a different ligand with other desirable properties. Examples of ligands are disclosed in U.S. Pat. Nos. 7,572,395, 8,143,703, 8,425,803, 8,563,133, 8,916,064, 9,005,480, 9,139,770, and 9,169,435, and in U.S. Patent Application Publication No. 2008/0118755.

Ligands suitable for the synthesis of an outer shell layer are known by those of skill in the art. In some embodiments, the ligand is a fatty acid selected from the group consisting of lauric acid, caproic acid, myristic acid, palmitic acid, stearic acid, and oleic acid. In some embodiments, the ligand is an organic phosphine or an organic phosphine oxide selected from trioctylphosphine oxide (TOPO), trioctylphosphine (TOP), diphenylphosphine (DPP), triphenylphosphine oxide, and tributylphosphine oxide. In some embodiments, the ligand is an amine selected from the group consisting of dodecylamine, oleylamine, hexadecylamine, dioctylamine, and octadecylamine. In some embodiments, the ligand is lauric acid.

Production of Outer Shell Layers on the Core with Thin Inner Shell

In some embodiments, the present invention is directed to a method of producing a nanostructure comprising:
(a) obtaining a solution comprising a first outer shell precursor;
(b) raising, lowering, or maintaining the temperature of the solution obtained in (a) to between about 50° C. and about 250° C.;
(c) adding a core/inner thin shell nanostructure to the solution of (b);
(d) adding a second outer shell precursor; and
(e) raising, lowering, or maintaining the temperature to between about 200° C. and about 350° C.;
   to provide a nanostructure.

In some embodiments, the present invention is directed to a method of producing a nanostructure comprising:
(a) obtaining a solution comprising a first outer shell precursor;
(b) raising, lowering, or maintaining the temperature of the solution obtained in (a) to between about 50° C. and about 250° C.;
(c) adding a core/inner thin shell nanostructure to the solution of (b);
(d) adding a second outer shell precursor;
(e) raising, lowering, or maintaining the temperature to between about 200° C. and about 350° C.; and
(f) adding a third outer shell precursor, wherein the third outer shell precursor in (f) is different from the second outer shell precursor in (d);
   to provide a nanostructure.

In some embodiments, the outer shell layer is produced in the presence of a solvent. In some embodiments, the solvent is selected from the group consisting of 1-octadecene, 1-hexadecene, 1-eicosene, eicosane, octadecane, hexadecane, tetradecane, squalene, squalane, trioctylphosphine oxide, trioctylamine, trioctylphosphine, and dioctyl ether. In some embodiments, the solvent is 1-octadecene.

In some embodiments, the solution comprising a first outer shell precursor obtained in (a) is at a temperature between about 20° C. and about 250° C., about 20° C. and about 200° C., about 20° C. and about 150° C., about 20° C. and 100° C., about 20° C. and about 50° C., about 50° C. and about 250° C., about 50° C. and 200° C., about 50° C. and about 150° C., about 50° C. and about 100° C., about 100° C. and about 250° C., about 100° C. and about 200° C., about 100° C. and about 150° C., about 150° C. and 250° C., about 150° C. and about 200° C., or about 200° C. and about 250° C. In some embodiments, the solution comprising a first outer shell precursor obtained in (a) is at a temperature between about 20° C. and about 250° C.

In some embodiments, the first outer shell precursor is a Group II precursor. In some embodiments, the first outer shell precursor is a zinc source or a cadmium source. In some embodiments, the first outer shell precursor is a zinc source.

In some embodiments, the solution in (a) further comprises at least one nanostructure ligand. Ligands can, e.g., enhance the miscibility of nanostructures in solvents or polymers (allowing the nanostructures to be distributed throughout a composition such that the nanostructures do not aggregate together), increase quantum yield of nanostructures, and/or preserve nanostructure luminescence (e.g., when the nanostructures are incorporated into a matrix). In some embodiments, the ligand(s) for the core synthesis and for the outer shell synthesis are the same. In some embodiments, the ligand(s) for the core synthesis and for the outer shell synthesis are different. Following synthesis, any ligand on the surface of the nanostructures can be exchanged for a different ligand with other desirable properties. Examples of ligands are disclosed in U.S. Pat. Nos. 7,572,395, 8,143,703, 8,425,803, 8,563,133, 8,916,064, 9,005,480, 9,139,770, and 9,169,435, and in U.S. Patent Application Publication No. 2008/0118755.

In some embodiments, the ligand admixed with the first outer shell precursor in (a) is a fatty acid selected from the group consisting of lauric acid, caproic acid, myristic acid, palmitic acid, stearic acid, and oleic acid. In some embodiments, the ligand is an organic phosphine or an organic phosphine oxide selected from trioctylphosphine oxide (TOPO), trioctylphosphine (TOP), diphenylphosphine (DPP), triphenylphosphine oxide, and tributylphosphine oxide. In some embodiments, the ligand is an amine selected from the group consisting of dodecylamine, oleylamine, hexadecylamine, dioctylamine, and octadecylamine. In some embodiments, the ligand is lauric acid.

In some embodiments, after introducing in (a) the first outer shell precursor, the temperature of the mixture is raised, lowered, or maintained in (b) to a temperature between about 50° C. and about 250° C., about 50° C. and 200° C., about 50° C. and about 150° C., about 50° C. and about 100° C., about 100° C. and about 250° C., about 100° C. and about 200° C., about 100° C. and about 150° C., about 150° C. and 250° C., about 150° C. and about 200° C., or about 200° C. and about 250° C. In some embodiments, after introducing in (a) the first shell precursor, the temperature of the mixture is raised, lowered, or maintained to a temperature between about 50° C. and about 250° C.

In some embodiments, the time for the temperature to reach the temperature in (b) is between about 2 minutes and about 240 minutes, about 2 minutes and about 200 minutes, about 2 minutes and about 100 minutes, about 2 minutes and about 60 minutes, about 2 minutes and about 40 minutes, about 5 minutes and about 240 minutes, about 5 minutes and about 200 minutes, about 5 minutes and about 100 minutes, about 5 minutes and about 60 minutes, about 5 minutes and about 40 minutes, about 10 minutes and about 240 minutes, about 10 minutes and about 200 minutes, about 10 minutes and about 100 minutes, about 10 minutes and about 60 minutes, about 10 minutes and about 40 minutes, about 40 minutes and about 240 minutes, about 40 minutes and about 200 minutes, about 40 minutes and about 100 minutes, about 40 minutes and about 60 minutes, about 60 minutes and about 240 minutes, about 60 minutes and about 200 minutes, about 60 minutes and about 100 minutes, about 100 minutes and about 240 minutes, about 100 minutes and about 200 minutes, or about 200 minutes and about 240 minutes.

In some embodiments, the nanostructure core in (c) comprises a nanocrystal selected from BN, BP, Bas, BSb, AlN, AlP, AlAs, AlSb, GaN, GaP, GaAs, GaSb, InN, InP, InAs, and InSb. In some embodiments, the nanostructure core in (c) comprises InP.

In some embodiments, the second outer shell precursor is a Group VI shell precursor. In some embodiments, the second outer shell precursor is sulfur, selenium, or tellurium. In some embodiments, the second outer shell precursor is a selenium source. In some embodiments, the selenium source is trioctylphosphine selenide.

In some embodiments, the temperature of the admixture in (e) is raised, lowered, or maintained to a temperature between about about 50° C. and about 350° C., about 50° C. and about 300° C., about 50° C. and about 250° C., about 50° C. and about 200° C., about 50° C. and about 150° C., about 50° C. and about 100° C., about 100° C. and about 350° C., about 100° C. and about 300° C., about 100° C. and about 250° C., about 100° C. and about 200° C., about 100° C. and about 150° C., about 150° C. and about 350° C., about 150° C. and about 300° C., about 150° C. and about 200° C., about 200° C. and about 350° C., about 200° C. and about 300° C., about 200° C. and about 250° C., about 250° C. and about 350° C., about 250° C. and about 300° C., or about 300° C. and about 350° C. In some embodiments, the temperature of the mixture is raised, lowered, or maintained in (e) to a temperature between about 250° C. and about 350° C.

In some embodiments, the temperature is maintained in (e) for a time between about 2 minutes and about 240 minutes, about 2 minutes and about 200 minutes, about 2 minutes and about 100 minutes, about 2 minutes and about 60 minutes, about 2 minutes and about 40 minutes, about 5 minutes and about 240 minutes, about 5 minutes and about 200 minutes, about 5 minutes and about 100 minutes, about 5 minutes and about 60 minutes, about 5 minutes and about 40 minutes, about 10 minutes and about 240 minutes, about 10 minutes and about 200 minutes, about 10 minutes and about 100 minutes, about 10 minutes and about 60 minutes, about 10 minutes and about 40 minutes, about 40 minutes and about 240 minutes, about 40 minutes and about 200 minutes, about 40 minutes and about 100 minutes, about 40 minutes and about 60 minutes, about 60 minutes and about 240 minutes, about 60 minutes and about 200 minutes, about 60 minutes and about 100 minutes, about 100 minutes and about 240 minutes, about 100 minutes and about 200 minutes, or about 200 minutes and about 240 minutes.

In some embodiments, the third outer shell precursor is a Group VI shell precursor. In some embodiments, the third outer shell precursor is sulfur, selenium, or tellurium. In some embodiments, the third outer shell precursor is a sulfur source. In some embodiments, the sulfur source is dodecanethiol.

In some embodiments, the temperature of the admixture in (f) is raised, lowered, or maintained at a temperature between about about 50° C. and about 350° C., about 50° C. and about 300° C., about 50° C. and about 250° C., about 50° C. and about 200° C., about 50° C. and about 150° C., about 50° C. and about 100° C., about 100° C. and about 350° C., about 100° C. and about 300° C., about 100° C. and about 250° C., about 100° C. and about 200° C., about 100° C. and about 150° C., about 150° C. and about 350° C., about 150° C. and about 300° C., about 150° C. and about 200° C., about 200° C. and about 350° C., about 200° C. and about 300° C., about 200° C. and about 250° C., about 250° C. and about 350° C., about 250° C. and about 300° C., or about 300° C. and about 350° C. In some embodiments, the temperature of the mixture is raised, lowered, or maintained in (f) to a temperature between about 250° C. and about 350° C.

In some embodiments, the temperature is maintained in (f) for a time between about 2 minutes and about 240 minutes, about 2 minutes and about 200 minutes, about 2 minutes and about 100 minutes, about 2 minutes and about 60 minutes, about 2 minutes and about 40 minutes, about 5 minutes and about 240 minutes, about 5 minutes and about 200 minutes, about 5 minutes and about 100 minutes, about 5 minutes and about 60 minutes, about 5 minutes and about 40 minutes, about 10 minutes and about 240 minutes, about 10 minutes and about 200 minutes, about 10 minutes and about 100 minutes, about 10 minutes and about 60 minutes, about 10 minutes and about 40 minutes, about 40 minutes and about 240 minutes, about 40 minutes and about 200 minutes, about 40 minutes and about 100 minutes, about 40 minutes and about 60 minutes, about 60 minutes and about 240 minutes, about 60 minutes and about 200 minutes, about 60 minutes and about 100 minutes, about 100 minutes and about 240 minutes, about 100 minutes and about 200 minutes, or about 200 minutes and about 240 minutes.

In some embodiments, additional shells are produced by further additions of shell precursors that are added to the reaction mixture followed by maintaining at an elevated temperature. Typically, additional shell precursor is provided after reaction of the previous shell is substantially complete (e.g., when at least one of the previous precursors is depleted or removed from the reaction or when no additional growth is detectable). The further additions of precursor create additional shells.

In some embodiments, the nanostructure is cooled before the addition of additional shell precursor to provide further shells. In some embodiments, the nanostructure is maintained at an elevated temperature before the addition of shell precursor to provide further shells.

After sufficient layers of shell have been added for the nanostructure to reach the desired thickness and diameter, the nanostructure can be cooled. In some embodiments, the nanostructures are cooled to room temperature. In some embodiments, an organic solvent is added to dilute the reaction mixture comprising the nanostructures.

In some embodiments, the organic solvent used to dilute the reaction mixture comprising the nanostructures is ethanol, hexane, pentane, toluene, benzene, diethylether, acetone, ethyl acetate, dichloromethane (methylene chloride), chloroform, dimethylformamide, N-methylpyrrolidinone, or combinations thereof. In some embodiments, the organic solvent is toluene.

In some embodiments, nanostructures are isolated. In some embodiments, the nanostructures are isolated by precipitation using an organic solvent. In some embodiments, the nanostructures are isolated by flocculation with ethanol.

The number of shells will determine the size of the nanostructures. The size of the nanostructures can be determined using techniques known to those of skill in the art. In some embodiments, the size of the nanostructures is determined using TEM. In some embodiments, the nanostructures have an average diameter of between 1 nm and 15 nm, between 1 nm and 10 nm, between 1 nm and 9 nm, between 1 nm and 8 nm, between 1 nm and 7 nm, between 1 nm and 6 nm, between 1 nm and 5 nm, between 5 nm and 15 nm, between 5 nm and 10 nm, between 5 nm and 9 nm, between 5 nm and 8 nm, between 5 nm and 7 nm, between 5 nm and 6 nm, between 6 nm and 15 nm, between 6 nm and 10 nm, between 6 nm and 9 nm, between 6 nm and 8 nm, between 6 nm and 7 nm, between 7 nm and 15 nm, between 7 nm and 10 nm, between 7 nm and 9 nm, between 7 nm and 8 nm, between 8 nm and 15 nm, between 8 nm and 10 nm, between 8 nm and 9 nm, between 9 nm and 15 nm, between 9 nm and 10 nm, or between 10 nm and 15 nm. In some embodiments, the nanostructures have an average diameter of between 6 nm and 7 nm.

### Nanostructure Properties

In some embodiments, the nanostructure is a core/inner thin shell/outer shell nanostructure or a core/inner thin shell/outer shell/outer shell nanostructure. In some embodiments, the nanostructure is a InP/ZnS/ZnSe/ZnS nanostructure.

In some embodiments, the nanostructures display a high photoluminescence quantum yield. In some embodiments, the nanostructures display a photoluminescence quantum yield of between about 60% and about 99%, about 60% and about 95%, about 60% and about 90%, about 60% and about 85%, about 60% and about 80%, about 60% and about 70%, about 70% and about 99%, about 70% and about 95%, about 70% and about 90%, about 70% and about 85%, about 70% and about 80%, about 80% and about 99%, about 80% and about 95%, about 80% and about 90%, about 80% and about 85%, about 85% and about 99%, about 85% and about 95%, about 80% and about 85%, about 85% and about 99%, about 85% and about 90%, about 90% and about 99%, about 90% and about 95%, or about 95% and about 99%. In some embodiments, the nanostructures display a photoluminescence quantum yield of between about 85% and about 96%.

The photoluminescence spectrum of the nanostructures can cover essentially any desired portion of the spectrum. In some embodiments, the photoluminescence spectrum for the nanostructures have a emission maximum between 300 nm and 750 nm, 300 nm and 650 nm, 300 nm and 550 nm, 300 nm and 450 nm, 450 nm and 750 nm, 450 nm and 650 nm, 450 nm and 550 nm, 450 nm and 750 nm, 450 nm and 650 nm, 450 nm and 550 nm, 550 nm and 750 nm, 550 nm and 650 nm, or 650 nm and 750 nm. In some embodiments, the photoluminescence spectrum for the nanostructures has an emission maximum of between 450 nm and 550 nm.

The size distribution of the nanostructures can be relatively narrow. In some embodiments, the photoluminescence spectrum of the population of nanostructures can have a full width at half maximum of between 10 nm and 60 nm, 10 nm and 40 nm, 10 nm and 30 nm, 10 nm and 20 nm, 20 nm and 60 nm, 20 nm and 40 nm, 20 nm and 30 nm, 30 nm and 60 nm, 30 nm and 40 nm, or 40 nm and 60 nm. In some embodiments, the photoluminescence spectrum of the population of nanostructures can have a full width at half maximum of between 35 nm and 50 nm.

### Increased Stokes Shift of the Nanostructures

In some embodiments, the nanostructures provide a high Stokes shift. Because the energy associated with fluorescence emission transitions is typically less than that of absorption, the resulting emitted photons have less energy and are shifted to longer wavelengths. This phenomenon is known as Stokes shift and occurs for virtually all fluorophores. The primary origin of the Stokes shift is the rapid decay of excited electrons to the lowest vibrational energy level of the 51 excited state. The Stokes shift is measured as the difference between the maximum wavelengths in the excitation and emission spectra of a particular fluorophore. If the shift in emission is toward shorter wavelengths (lower wavenumbers), the shift is an anti-Stokes shift. If the shift in emission is toward longer wavelengths (higher wavenumbers), the shift is a Stokes” shift.

The size of the shift varies with molecular structure, but can range from just a few nanometers to over several hundred nanometers. For example, the Stokes shift of fluorescein is approximately 20 nanometers and the Stokes shift for quinine is 110 nanometers.

The effective Stokes shift is measured as the difference between the lowest energy peak wavelength in the absorbance spectra and the peak wavelength in the emission spectra. In some embodiments, the nanostructures exhibit an effective Stokes shift of between about 25 nm and about 125 nm, about 25 nm and about 100 nm, about 25 nm and about 75 nm, about 25 nm and about 50 nm, about 25 nm and about 40 nm, about 25 nm and about 30 nm, about 30 nm and about 125 nm, about 30 nm and about 100 nm, about 30 nm and about 75 nm, about 30 nm and about 50 nm, about 30 nm and about 40 nm, 40 nm and about 125 nm, about 40 nm and about 100 nm, about 40 nm and about 75 nm, about 40 nm and about 50 nm, about 50 nm and about 125 nm, about 50 nm and about 100 nm, about 50 nm and about 75 nm, about 75 nm and about 125 nm, about 75 nm and about 100 nm, or about 100 nm and about 125 nm. In some embodiments, the nanostructures exhibit an effective Stokes shift of between about 30 nm and about 40 nm.

### Peak Emission Wavelength

In some embodiments, the nanostructures emit light having a peak emission wavelength (PWL) between about 400 nm and about 650 nm, about 400 nm and about 600 nm, about 400 nm and about 550 nm, about 400 nm and about 500 nm, about 400 nm and about 450 nm, about 450 nm and about 650 nm, about 450 nm and about 600 nm, about 450 nm and about 550 nm, about 450 nm and about 500 nm, about 500 nm and about 650 nm, about 500 nm and about 600 nm, about 500 nm and about 550 nm, about 550 nm and about 650 nm, about 550 nm and about 600 nm, or about 600 nm and about 650 nm. In some embodiments, the nanostructures emit light having a PWL between about 500 nm and about 550 nm.

### Films, Devices and Uses

A population of core/inner thin shell nanostructures or core/inner thin shell/outer shell nanostructures are optionally embedded in a matrix that forms a film (e.g., an organic polymer, silicon-containing polymer, inorganic, glassy, and/or other matrix). This film may be used in production of a nanostructure phosphor, and/or incorporated into a device, e.g., an LED, backlight, downlight, or other display or lighting unit or an optical filter. Exemplary phosphors and lighting units can, e.g., generate a specific color light by incorporating a population of nanostructures with an emission maximum at or near the desired wavelength or a wide color gamut by incorporating two or more different populations of nanostructures having different emission maxima. A variety of suitable matrices are known in the art. See, e.g., U.S. Pat. No. 7,068,898 and U.S. Patent Application Publication Nos. 2010/0276638, 2007/0034833, and 2012/0113672. Exemplary nanostructure phosphor films, LEDs, backlighting units, etc. are described, e.g., in U.S. Patent Application Publications Nos. 2010/0276638, 2012/0113672, 2008/0237540, 2010/0110728, and 2010/0155749 and U.S. Pat. Nos. 7,374,807, 7,645,397, 6,501,091, and 6,803,719.

The resulting nanostructures can be used for imaging or labeling, e.g., biological imaging or labeling. Thus, the resulting nanostructures are optionally covalently or noncovalently bound to biomolecule(s), including, but not limited to, a peptide or protein (e.g., an antibody or antibody domain, avidin, streptavidin, neutravidin, or other binding or recognition molecule), a ligand (e.g., biotin), a polynucleotide (e.g., a short oligonucleotide or longer nucleic acid), a carbohydrate, or a lipid (e.g., a phospholipid or other micelle). One or more nanostructures can be bound to each biomolecule, as desired for a given application. Such nanostructure-labeled biomolecules find use, for example, in vitro, in vivo, and in cellulo, e.g., in exploration of binding or chemical reactions as well as in subcellular, cellular, and organismal labeling.

Nanostructures resulting from the methods are also a feature of the invention. Thus, one class of embodiments provides a population of nanostructures. In some embodiments, the nanostructures are quantum dots.

### EXAMPLES

The following examples are illustrative and non-limiting, of the products and methods described herein. Suitable modifications and adaptations of the variety of conditions, formulations, and other parameters normally encountered in the field and which are obvious to those skilled in the art in view of this disclosure are within the spirit and scope of the invention.

### Example 1

### Preparation of an InP/ZnS/ZnSe/ZnS (1 Equivalent Inner Shell)

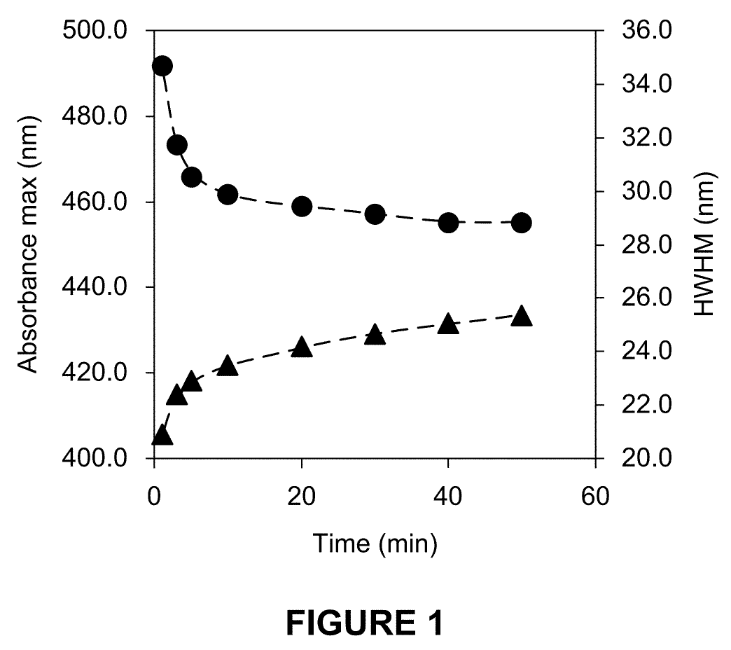

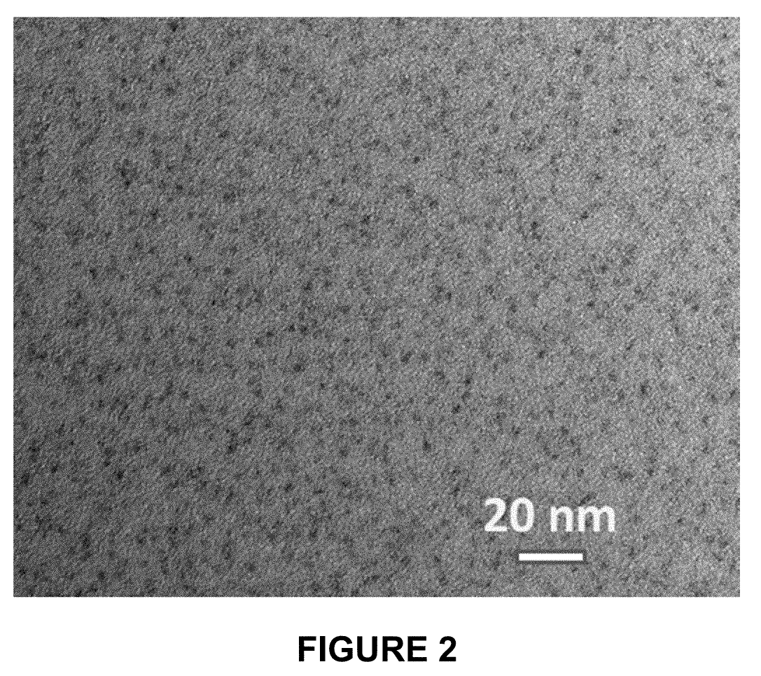

InP/ZnS core/inner thin shell nanostructures with 1 equivalent of inner ZnS shell were made by combining indium myristate (0.4 mmol), zinc oleate (0.4 mmol), dodecanethiol (0.4 mmol), and tris(trimethylsilyl)phosphine (0.4 mmol) in octadecene (32 mL). All materials were degassed under vacuum at room temperature and heated to 300° C. under an N₂ atmosphere. Reaction progress was tracked by removing small aliquots and monitoring the UV-vis absorbance spectra. The reaction was stopped when the absorbance maximum (as shown in FIG. 1) was >430 nm by removing the heat source from the reaction. Once cooled to room temperature, the InP/ZnS core/inner thin shell nanostructure was precipitated with one volume of acetone and dispersed as the isolated material in hexane (5 mL). Transmission electron micrographs of the isolated InP/ZnS core/inner thin shell nanostructures are shown in FIG. 2. The reaction was scaled ten-fold and produced equivalent results. Core/inner thin shell nanostructures grown using this method display small half width at half maximum (HWHM) as shown in FIG. 1, and small valley/peak (V/P) metrics as shown in TABLE 1.

TABLE 1
Optical Properties of InP/ZnS Core/Inner Thin
Shells Synthesized Using a Heat-up Method

| | Molar Ratio | λ_{abs} | HWHM | |
|---|---|---|---|---|
| Compound | (S:In) | (nm) | (nm) | V/P |
| 1 | 1 | 433.4 | 28.7 | 0.65 |
| 2 | 0.5 | 435.3 | 27.8 | 0.60 |

As shown in TABLE 1, decreasing the molar ratio of sulfur (S) precursor to indium (In) precursor in the reaction results in modest improvements to the HWHM and V/P metrics.

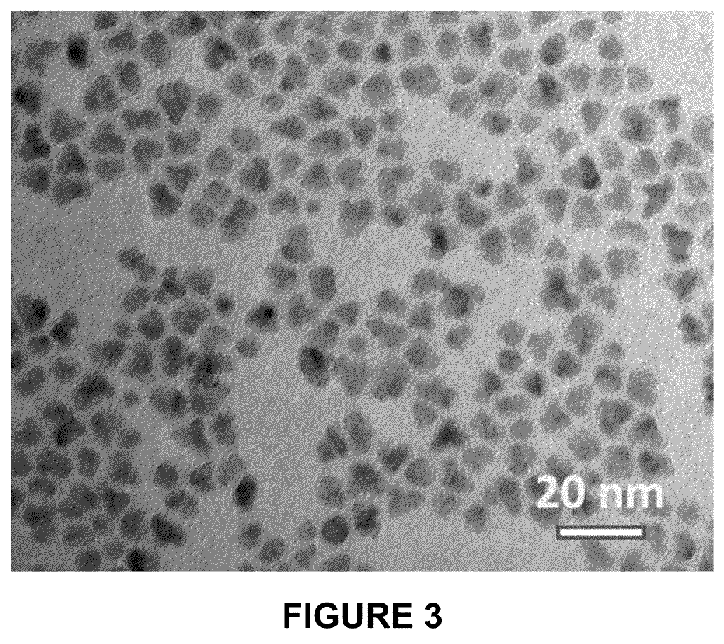

Further ZnSe and ZnS outer layers were grown as a secondary reaction on the isolated InP/ZnS core/inner thin shell nanostructure. Zinc oleate (6.2 mmol), lauric acid (6.2 mmol), and octadecene (11 mL) were degassed under vacuum and then heated under an N₂ atmosphere. The InP/ZnS core/thin shell nanostructure (0.14 mmol InP) was added to the reaction flask once the temperature was between 85-145° C. Trioctylphosphine selenide (equivalent amount to form 2.7 monolayers of ZnSe) was added to the reaction flask when the temperature was between 250-310° C. Following the formation of the ZnSe layer, dodecanethiol (equivalent amount to form 2.0 monolayers of ZnS) was added to the reaction flask when the temperature was between 250-310° C. Following the formation of the outer ZnS layer, the reaction was stopped by removing the heating source. The material was isolated by the addition of 0.5 vol trioctylphosphine, 1 vol toluene, and 2 vol ethanol and dispersed as the isolated material in hexane (10 mL). A transmission electron micrograph of the isolated InP/ZnS/ZnSe/ZnS nanostructure is shown in FIG. 3.

### Example 2

### Preparation of an InP/ZnS/ZnSe/ZnS (0.5 Equivalent Thin Shell)

InP/ZnS core/inner thin shell nanostructures with 0.5 equivalents of thin ZnS shell were made by combining indium myristate (0.4 mmol), zinc oleate (0.4 mmol), dodecanethiol (0.2 mmol), and tris(trimethylsilyl)phosphine (0.4 mmol) in octadecene (32 mL). All materials were degassed under vacuum at room temperature and heated to 300° C. under an N₂ atmosphere. Reaction progress was tracked by removing small aliquots and monitoring the UV-vis absorbance spectra. The reaction was stopped when the absorbance maximum was >435 nm by removing the heat source from the reaction. Once cooled to room temperature, the InP/ZnS core/inner thin shell nanostructure was precipitated with one volume of acetone and dispersed as the isolated material in hexane (5 mL).

Further ZnSe and ZnS outer layers were grown as a secondary reaction on the isolated InP/ZnS core/inner thin shell nanostructure. Zinc oleate (6.2 mmol), lauric acid (6.2 mmol), and octadecene (11 mL) were degassed under vacuum and then heated under an N₂ atmosphere. The InP/ZnS core/inner thin shell nanostructure (0.14 mmol InP) was added to the reaction flask once the temperature was between 85-145° C. Trioctylphosphine selenide (equivalent amount to form 2.7 monolayers of ZnSe) was added to the reaction flask when the temperature was between 250-310° C. Following the formation of the ZnSe layer, dodecanethiol (equivalent amount to form 2.0 monolayers of ZnS) was added to the reaction flask when the temperature was between 250-310° C. Following the formation of the outer ZnS layer, the reaction was stopped by removing the heating source. The material was isolated by the addition of 0.5 vol trioctylphoshine, 1 vol toluene, and 2 vol ethanol and dispersed as the isolated material in hexane (10 mL).

### Example 3

### Preparation of InP/ZnS Core/Inner Thin Shell Alternative Method

The effects of introducing a wide-band gap inner ZnS shell may also be observed following the growth of an thin ZnS shell in a secondary reaction on isolated and purified InP cores. Zinc oleate (5.4 mmol), lauric acid (5.4 mmol), and octadecene (11 mL) were combined in a flask. The reaction flask and contents were degassed under vacuum at room temperature and then heated under an N₂ atmosphere. Isolated InP cores (0.14 mmol InP) were added when the temperature was between 85-145° C. A low-temperature reactive sulfur-precursor (equivalent amount to form 1 monolayer of ZnS) was added to the reaction flask. Following the formation of the inner thin ZnS shell layer, subsequent ZnSe and ZnS shell layers were grown as described in Example 1 via the addition of trioctylphosphine selenide and dodecanethiol in amounts equivalent to form 0-2.0 monolayers of ZnSe and 0-2.0 monolayers of ZnS. The final product was isolated by the addition of 0.5 vol trioctylphoshine, 1 vol toluene, and 2 vol ethanol and dispersed as the isolated material in hexane (10 mL).

An thin ZnS shell may also be formed in the original InP core reaction via the introduction of a zinc carboxylate precursor and an alkanethiol at temperatures between 230-300° C. following the formation of the InP core.

### Example 4

### Comparison of Shell Structures

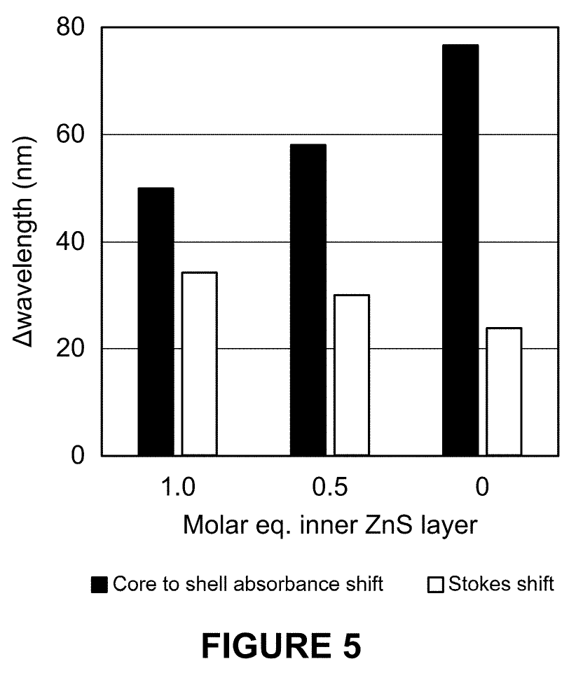

Upon further shelling of the InP/ZnS core/inner thin shell with ZnSe and ZnS outer shell layers, the average quantum dot diameter increased from 2.1 nm for the InP/ZnSe core/inner thin shell nanostructure, to 6.8 nm for the final InP/ZnS/ZnSe/ZnS nanostructure (compare FIG. 2 and FIG. 3). As compared to similar ZnSe/ZnS structures grown onto InP cores, the effective Stokes shift of the InP/ZnS/ZnSe/ZnS core/inner thin shell structures is larger (34 nm versus 24 nm) as shown in TABLE 2 and FIG. 5. Moreover, the size of the effective Stokes shift can be controlled by the molar equivalents of S introduced in the InP/ZnS core synthesis.

TABLE 2
Optical Properties of Nanostructures.

| | Core abs | λ_{abs} | PWL | Stokes shift | FWHM | PLQY | OD₄₅₀/ |
|---|---|---|---|---|---|---|---|
| Shell Structure | (nm) | (nm) | (nm) | (nm) | (nm) | (%) | peak |
| InP/ZnS/ZnSe/ZnS | 432.4 | 482.2 | 516.4 | 34.2 | 46.3 | 88.2% | 0.8 |
| (1.0 eq inner ZnS) | | | | | | | |
| InP/ZnS/ZnSe/ZnS | 434.4 | 492.4 | 522.4 | 30.0 | 42.3 | 86.7% | 0.8 |
| (0.5 eq inner ZnS) | | | | | | | |
| InP/ZnSe/ZnS | 432.5 | 509.1 | 532.9 | 23.8 | 38.6 | 92.2% | 1.1 |

In addition to increasing the size of the effective Stokes shift, the introduction of an inner ZnS shell layer increases the quantum confinement of the exciton wavefunction to the InP core as evidenced by a decreased redshift upon the growth of the outer ZnSe shell (50 versus 77 nm core-to-core/shell redshift (as shown in FIG. 5)). Increased excitonic confinement served to control the emission wavelength (PWL<523 nm), allowing for use in high optical density applications and may also limit PLQY sensitivity to decreased surface ligand density by limiting exciton access to surface trap sites.

Measured absorption and emission spectra of the materials can be used to calculate the losses due to reabsorption for films of varying optical density and quantum yield. Such optical modeling shows that despite broader FWHM values for the InP/ZnS/ZnSe/ZnS core/inner thin shell nanostructures compared to those for standard materials (46 nm versus<40 nm (see TABLE 2)), the larger Stokes shift would still result in reduced losses due to reabsorption.

While various embodiments have been described above, it should be understood that they have been presented by way of example only, and not limitation. It will be apparent to persons skilled in the relevant art that various changes in form and detail can be made therein without departing from the spirit and scope of the invention. Thus, the breadth and scope should not be limited by any of the above-described exemplary embodiments, but should be defined only in accordance with the following claims and their equivalents.

All publications, patents and patent applications mentioned in this specification are indicative of the level of skill of those skilled in the art to which this invention pertains, and are herein incorporated by reference to the same extent as if each individual publication, patent or patent application was specifically and individually indicated to be incorporated by reference.

1. A nanostructure comprising a nanocrystal core and at least one thin inner shell, wherein the at least one thin inner shell has a thickness of between about 0.01 nm and about 0.35 nm, and wherein the nanostructure exhibits an effective Stokes shift of between about 25 nm and about 125 nm.

2. The nanostructure of claim 1, wherein the nanocrystal core is selected from the group consisting of Si, Ge, Sn, Se, Te, B, C, P, BN, BP, BAs, AlN, AlP, AlAs, AlSb, GaN, GaP, GaAs, GaSb, InN, InP, InAs, InSb, ZnO, ZnS, ZnSe, ZnTe, CdS, CdSe, CdSeZn, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, Al₂CO₃ and combinations thereof.

3. (canceled)

4. The nanostructure of claim 1, wherein the at least one thin inner shell is selected from the group consisting of CdS, CdSe, CdO, CdTe, ZnS, ZnO, ZnSe, ZnTe, MgTe, GaAs, GaSb, GaN, HgO, HgS, HgSe, HgTe, InAs, InSb, InN, AlAs, AlN, AlSb, AlS, PbS, PbO, PbSe, PbTe, MgO, MgS, MgSe, MgTe, CuCl, Ge, Si, and alloys thereof.

5.-6. (canceled)

7. The nanostructure of claim 1, wherein the thickness of the at least one thin inner shell is between about 0.01 nm and about 0.25 nm.

8. (canceled)

9. The nanostructure of claim 1, wherein the nanostructure exhibits an effective Stokes shift of between about 25 nm and about 50 nm.

10. (canceled)

11. The nanostructure of claim 1, wherein the at least one outer shell is further comprising at least one outer shell selected from the group consisting of CdS, CdSe, CdO, CdTe, ZnS, ZnO, ZnSe, ZnTe, MgTe, GaAs, GaSb, GaN, HgO, HgS, HgSe, HgTe, InAs, InSb, InN, AlAs, AlN, AlSb AlS, PbS, PbO, PbSe, PbTe, MgO, MgS, MgSe, MgTe, CuCl, Ge, Si, and alloys thereof.

12.-13. (canceled)

14. The nanostructure of claim 11, wherein the nanocrystal core comprises InP, wherein the at least one thin inner shell comprises ZnS, further comprising two outer shells, and wherein the nanostructure exhibits an effective Stokes shift of between about 25 nm and about 50 nm.

15. A method of making the nanostructure of claim 1, comprising:
(a) admixing a first core precursor, a second core precursor, a first inner shell precursor, and a second inner shell precursor; and
(b) raising the temperature of the admixture in (a) to a temperature between about 200° C. and about 350° C.;
to provide a nanostructure.

16.-19. (canceled)

20. The method of claim 15, wherein the first core precursor is selected from the group consisting of a cadmium source, a zinc source, an aluminum source, a gallium source, or an indium source.

21. (canceled)

22. The method of claim 15, wherein the second core precursor is selected from the group consisting of a phosphorus source, a nitrogen source, an arsenic source, a sulfur source, a selenium source, or a tellurium source.

23. (canceled)

24. The method of claim 15, wherein the first inner shell precursor is selected from the group consisting of a cadmium source, a zinc source, an aluminum source, a gallium source, or an indium source.

25. (canceled)

26. The method of claim 15, wherein the second inner shell precursor is selected from the group consisting of a phosphorus source, a nitrogen source, an arsenic source, a sulfur source, a selenium source, or a tellurium source.

27. (canceled)

28. The method of claim 15, wherein the first core precursor comprises indium myristate, the second core precursor comprises tris(trimethyl)phosphine, the first inner shell precursor comprises zinc oleate, and the second inner shell precursor comprises dodecanethiol.

29.-31. (canceled)

32. A method of making the nanostructure of claim 1, comprising:
(a) admixing a first inner shell precursor and a solvent;
(b) raising, lowering, or maintaining the temperature of the admixture in (a) to a temperature between about 50° C. and about 250° C.; and
(c) adding a nanostructure core and a second inner shell precursor to the admixture in (b);
to provide a nanostructure.

33.-35. (canceled)

36. The method of claim 32, wherein the first inner shell precursor is selected from the group consisting of a cadmium source, a zinc source, an aluminum source, a gallium source, or an indium source.

37.-38. (canceled)

39. The method of claim 32, wherein the nanostructure core in (c) is selected from the group consisting of Si, Ge, Sn, Se, Te, B, C, P, BN, BP, BAs, AlP, AlAs, AlSb, GaN, GaP, GaAs, GaSb, InN, InP, InAs, InSb, ZnO, ZnS, ZnSe, ZnTe, CdS, CdSe, CdSeZn, CdTe, HgS, HgSe, HgTe, BeS, BeSe, BeTe, MgS, MgSe, GeS, GeSe, GeTe, SnS, SnSe, SnTe, PbO, PbS, Pb Se, PbTe, CuF, CuCl, CuBr, CuI, Si₃N₄, Ge₃N₄, Al₂O₃, Al₂CO₃ and combinations thereof.

40. (canceled)

41. The method of claim 32, wherein the second inner shell precursor is selected from the group consisting of a phosphorus source, a nitrogen source, an arsenic source, a sulfur source, a selenium source, or a tellurium source.

42. (canceled)

43. The method of claim 32, wherein the first inner shell precursor comprises zinc oleate, the nanostructure core comprises InP, and the second inner shell precursor comprises dodecanethiol.

44.-45. (canceled)

46. A method of making the nanostructure of claim 1 comprising:
(a) obtaining a solution comprising a first outer shell precursor;
(b) raising, lowering, or maintaining the temperature of the solution obtained in (a) to between about 50° C. and about 250° C.;
(c) adding the core/inner thin shell nanostructure prepared by the method of claim 15 to the solution of (b);
(d) adding a second outer shell precursor; and
(e) raising, lowering, or maintaining the temperature to between about 200° C. and about 350° C.;
to provide a nanostructure.

47. The method of claim 46, further comprising:
(f) adding a third outer shell precursor, wherein the third outer shell precursor in (f) is different from the second outer shell precursor in (d).

48.-51. (canceled)

52. The method of claim 46, wherein the first outer shell precursor is selected from the group consisting of a cadmium source, a zinc source, an aluminum source, a gallium source, or an indium source.

53.-55. (canceled)

56. The method of claim 46, wherein the second outer shell precursor is selected from the group consisting of a phosphorus source, a nitrogen source, an arsenic source, a sulfur source, a selenium source, or a tellurium source.

57.-58. (canceled)

59. The method of claim 47, wherein the third outer shell precursor is selected from the group consisting of a phosphorus source, a nitrogen source, an arsenic source, a sulfur source, a selenium source, or a tellurium source.

60. (canceled)

61. The method of claim 47, wherein the first outer shell precursor comprises zinc oleate, the second outer shell precursor comprises trioctylphosphine selenide, and the third outer shell precursor comprises dodecanethiol.

62. (canceled)
